(19) United States
(12) Patent Application Publication
(10) Pub. No.: US 2025/0357277 A1
(43) Pub. Date: Nov. 20, 2025

(54) Through Via Power Delivery Structure for Stacked Chips

(71) Applicant: Taiwan Semiconductor Manufacturing Company, Ltd., Hsin-Chu (TW)

(72) Inventors: Chih-Chieh CHANG, Hsinchu (TW); Kuan-Hsun WANG, Hsinchu County (TW); Chih Hsin YANG, Hsinchu County (TW); Mao-Nan WANG, Kaohsiung City (TW); Yang-Hsin SHIH, Hsinchu City (TW); Yun-Sheng LI, Hsinchu (TW); Liang-Wei WANG, Hsinchu City (TW)

(21) Appl. No.: 19/283,389

(22) Filed: Jul. 29, 2025

Related U.S. Application Data
(63) Continuation of application No. 18/750,860, filed on Jun. 21, 2024.
(60) Provisional application No. 63/621,454, filed on Jan. 16, 2024.

(51) Int. Cl. H01L 23/48; H01L 21/768; H01L 23/00; H01L 23/31; H01L 23/522; H01L 23/58; H01L 25/065

(52) U.S. Cl. CPC H01L 23/481; H01L 21/76816; H01L 21/76898; H01L 23/585; H01L 24/08; H01L 25/0657; H01L 23/31; H01L 23/522; H01L 2224/08145

(57) ABSTRACT

Through via power delivery structures for chip stacks and methods of fabrication thereof are disclosed. An exemplary stacked chip structure includes a first chip and a second chip. The first chip has a first substrate, a first device layer, and a first interconnect structure. The second chip has a second substrate, a second device layer, and a second interconnect structure. A first through via extends through the first substrate, the first device layer, the first interconnect structure, and into the second interconnect structure. A second through via extends through the first substrate, the first device layer, and into the first interconnect structure. The second through via and the first through via may be electrically connected to the first device layer and the second device layer, respectively, and power may be delivered to the first device layer and the second device layer via the second through via and the first through via, respectively.

This is a continuation application of U.S. patent application Ser. No. 18/750,860, filed Jun. 21, 2024, which is a non-provisional application of and claims benefit of U.S. Provisional Patent Application Ser. No. 63/621,454, filed Jan. 16, 2024, the entire disclosures of which are incorporated herein by reference.

### BACKGROUND

Advanced integrated circuit (IC) packaging technologies have been explored to further reduce density and/or improve performance of ICs. For example, IC packaging has evolved, such that multiple ICs may be vertically stacked in three-dimensional (“3D”) packages or 2.5D packages (e.g., packages that implement an interposer). Although existing power delivery structures for stacked ICs of advanced IC packages have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with standard practice in the industry, various features are not drawn to scale and are used for illustration purposes only. Dimensions of the various features may be arbitrarily increased or reduced for clarity of discussion.

FIG. 1 is a cross-sectional view of a stacked chip structure, in portion or entirety, having a power delivery structure according to various aspects of the present disclosure.

FIG. 2A is a cross-sectional view of the stacked chip structure, in portion or entirety, having another power delivery structure according to various aspects of the present disclosure.

FIG. 2B is a cross-sectional view of the stacked chip structure, in portion or entirety, having another power delivery structure according to various aspects of the present disclosure.

FIG. 3A, FIG. 3B, FIG. 3C, FIG. 3D, and FIG. 3E are enlarged, cross-sectional views of respective portions of the stacked chip structure of FIG. 1 and/or the stacked chip structure of FIG. 2A, according to various aspects of the present disclosure.

FIG. 4A, FIG. 4B, and FIG. 4C are top views of different configurations of guard rings that may be formed around a through via, in portion or entirety, and that may be implemented in the stacked chip structure of FIG. 1 and/or the stacked chip structure of FIG. 2A, according to various aspects of the present disclosure.

FIG. 5A is a plan view of the power delivery structure, in portion or entirety, of the stacked chip structure of FIG. 2A, according to various aspects of the present disclosure.

FIG. 5B is another plan view of the power delivery structure, in portion or entirety, of the stacked chip structure of FIG. 2A, according to various aspects of the present disclosure.

FIG. 6A is a plan view of the power delivery structure, in portion or entirety, of the stacked chip structure of FIG. 1, according to various aspects of the present disclosure.

FIG. 6B is a plan view of the power delivery structure, in portion or entirety, of the stacked chip structure of FIG. 2A, according to various aspects of the present disclosure.

FIG. 7A, FIG. 7B, FIG. 7C, FIG. 7D, FIG. 7E, FIG. 7F, FIG. 7G, FIG. 7H, FIG. 7I, and FIG. 7J are plan views of power delivery structures, in portion or entirety, having various configurations that may be implemented in at least the stacked chip structures of FIG. 2A and FIG. 2B, according to various aspects of the present disclosure.

FIG. 8 is a cross-sectional view of another stacked chip structure, in portion or entirety, having a power delivery structure according to various aspects of the present disclosure.

FIGS. 9-17 are cross-sectional views of the stacked chip structure of FIG. 1, in portion or entirety, during fabrication, according to various aspects of the present disclosure.

FIGS. 18-26 are cross-sectional views of the stacked chip structure of FIG. 2A, in portion or entirety, during fabrication, according to various aspects of the present disclosure.

### DETAILED DESCRIPTION

The present disclosure relates generally to integrated circuit (IC) packaging, and more particularly, to improved power delivery structures for stacked chips.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first feature and the second feature are formed in direct contact and may also include embodiments in which additional features may be formed between the first feature and the second feature, such that the first feature and the second feature may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure to describe one feature's relationship to another feature. The spatially relative terms are intended to cover different orientations of the device including the features.

Furthermore, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. In another example, two features described as having “substantially the same” dimension and/or “substantially” oriented in a particular direction and/or configuration (e.g., “substantially parallel” or “substantially perpendicular”) encompasses dimension differences between the two features and/or slight orientation variances of the two features from the exact specified orientation that may arise inherently, but not intentionally, from manufacturing tolerances associated with fabricating the two features. Still further, the present disclosure may repeat reference numerals and/or letters in the various examples. This repetition is for the purpose of simplicity and clarity and does not in itself dictate a relationship between the various embodiments and/or configurations described herein.

Through via power delivery structures for stacked chip structures are disclosed herein that may lower resistance-capacitance (RC) delay, improve power delivery efficiency, reduce area consumed by a power delivery structure of an IC package and thus improve chip (die) area utilization, reduce through via pitch, increase power delivery design flexibility (e.g., by untethering through via dimensions (e.g., through via pitch) from chip bonding pitches), or combinations thereof. Through via power delivery structures described herein may provide a power-delivery through via for each chip of a stacked chip structure. Different embodiments may have different advantages, and no particular advantage is required of any embodiment.

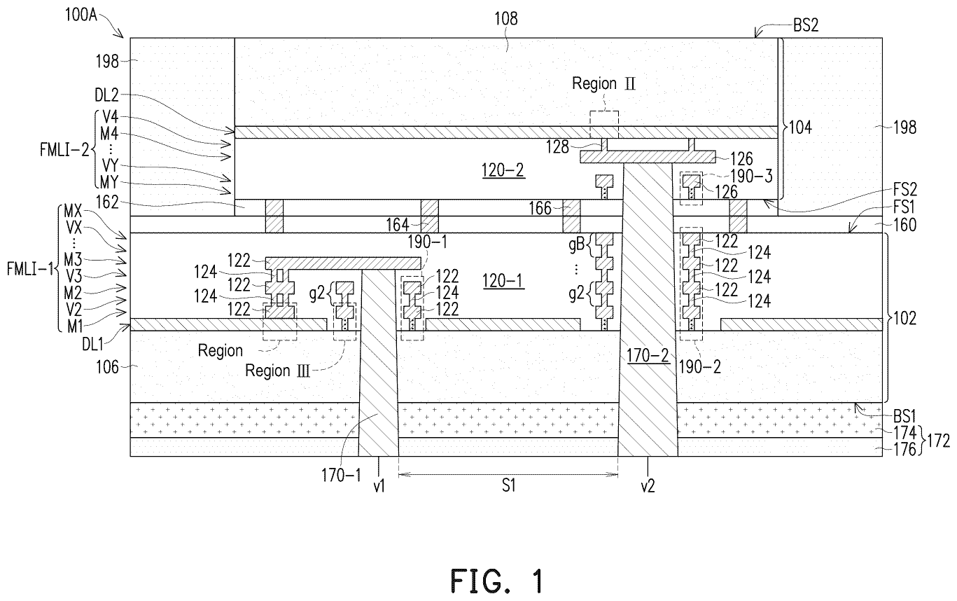

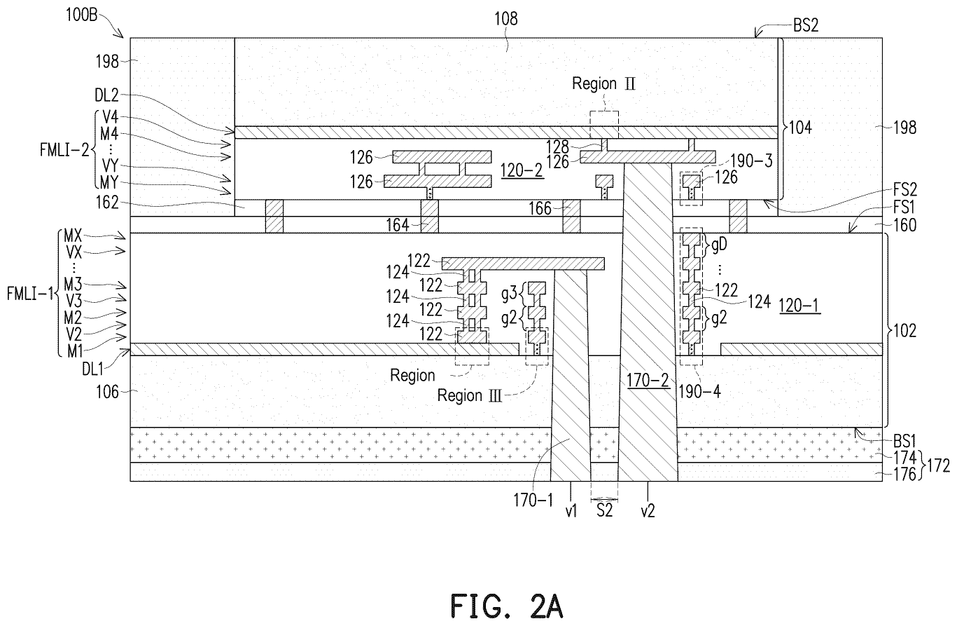

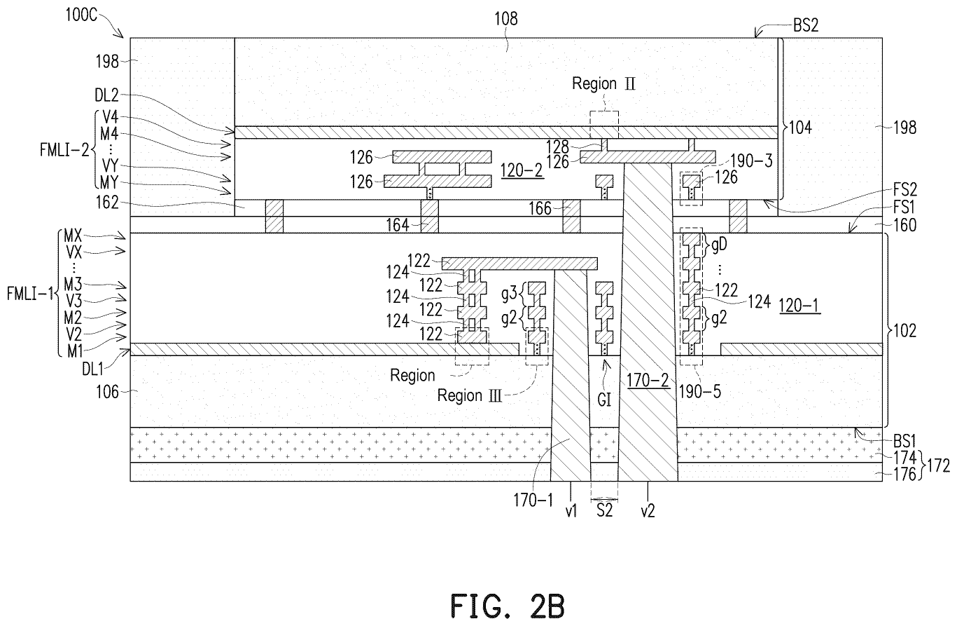

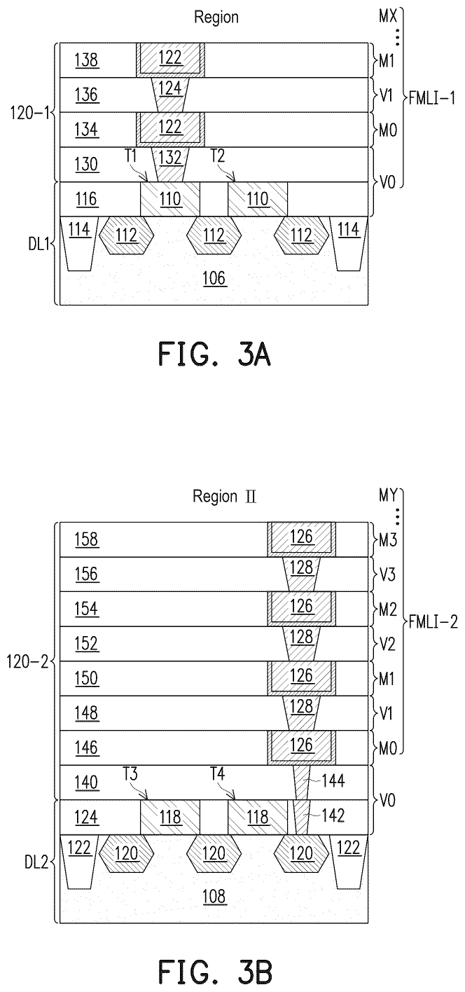

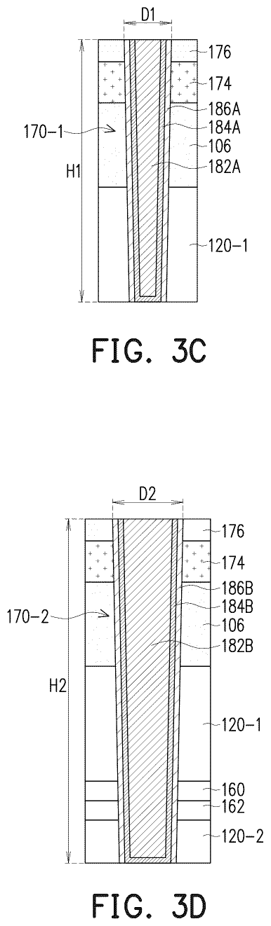

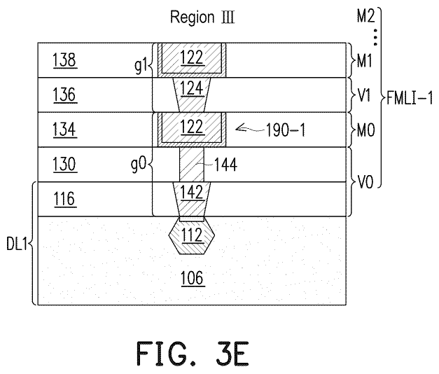

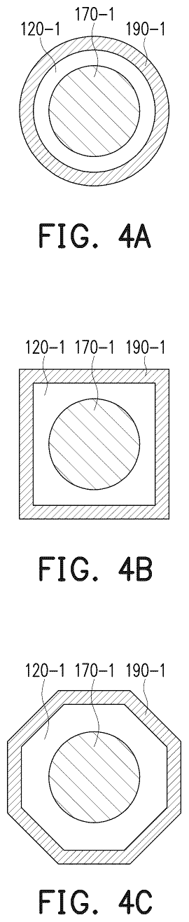

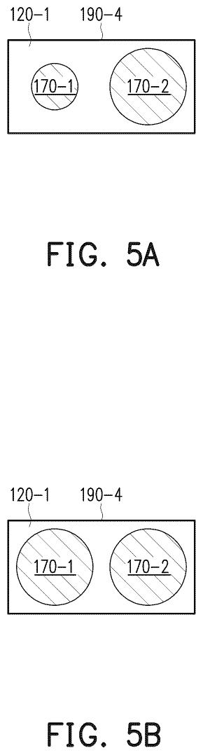

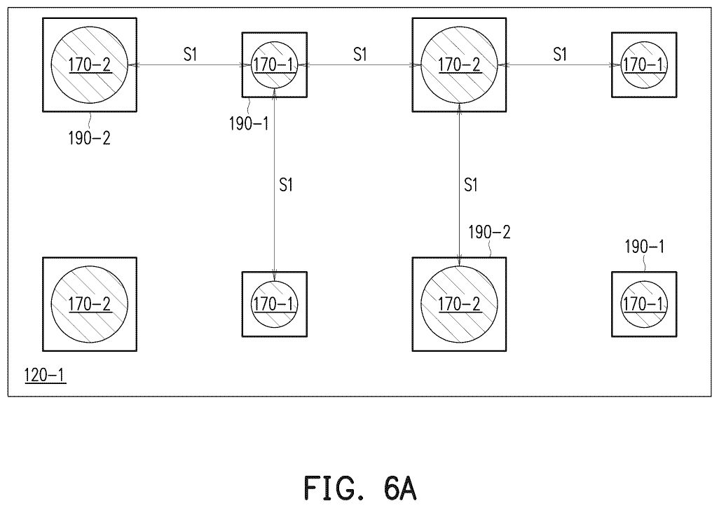

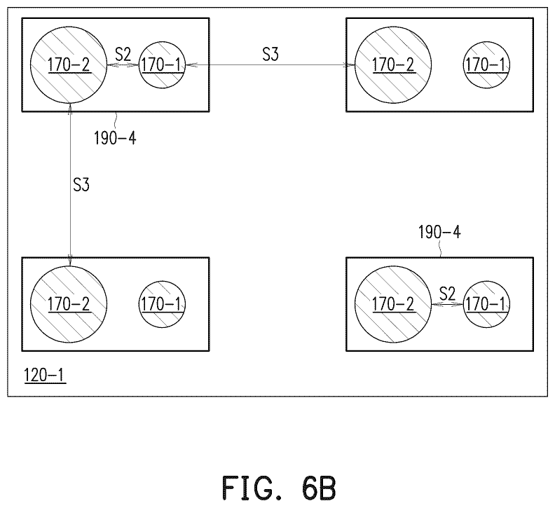

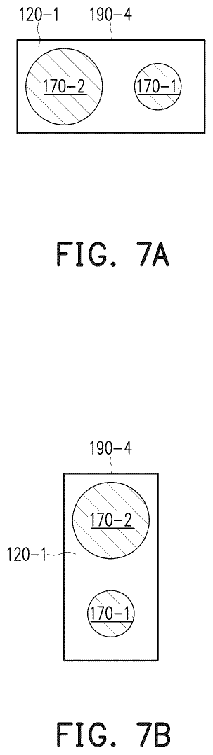

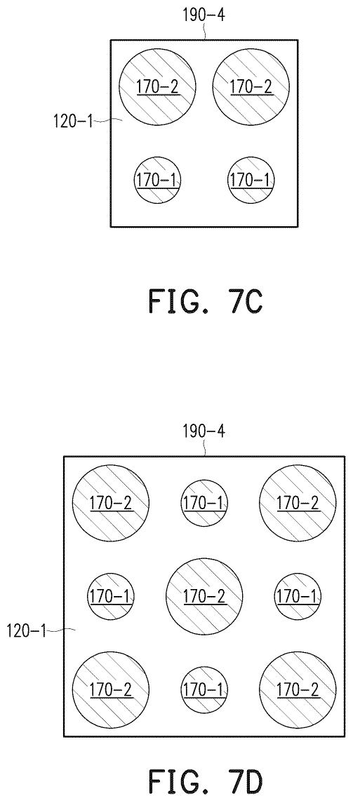

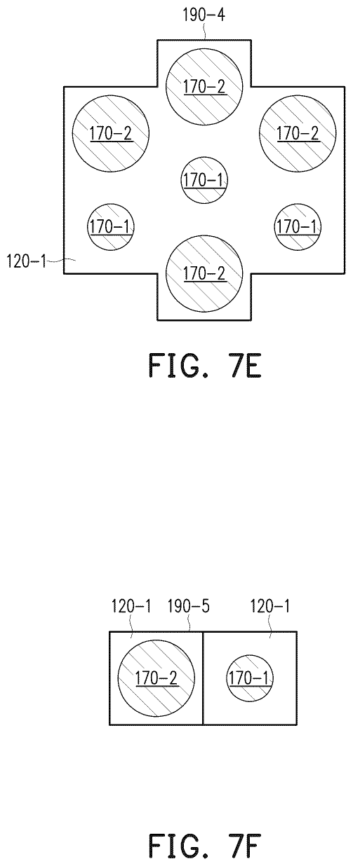

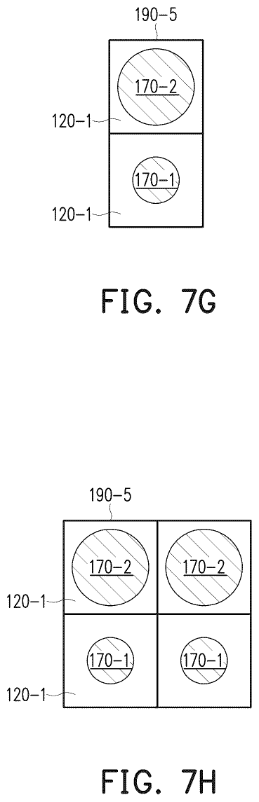

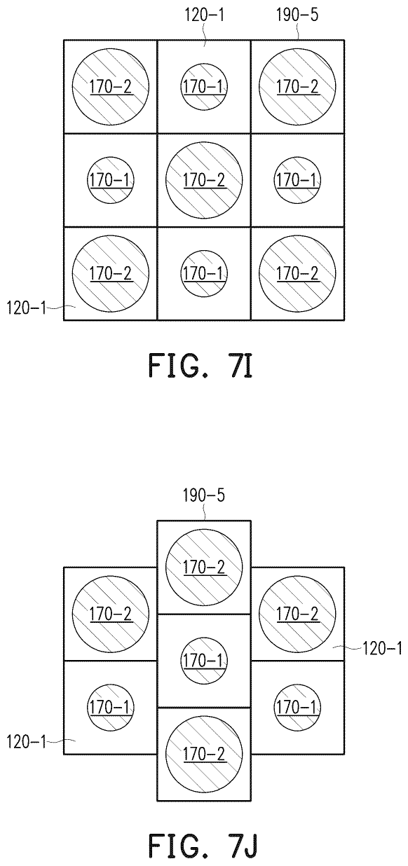

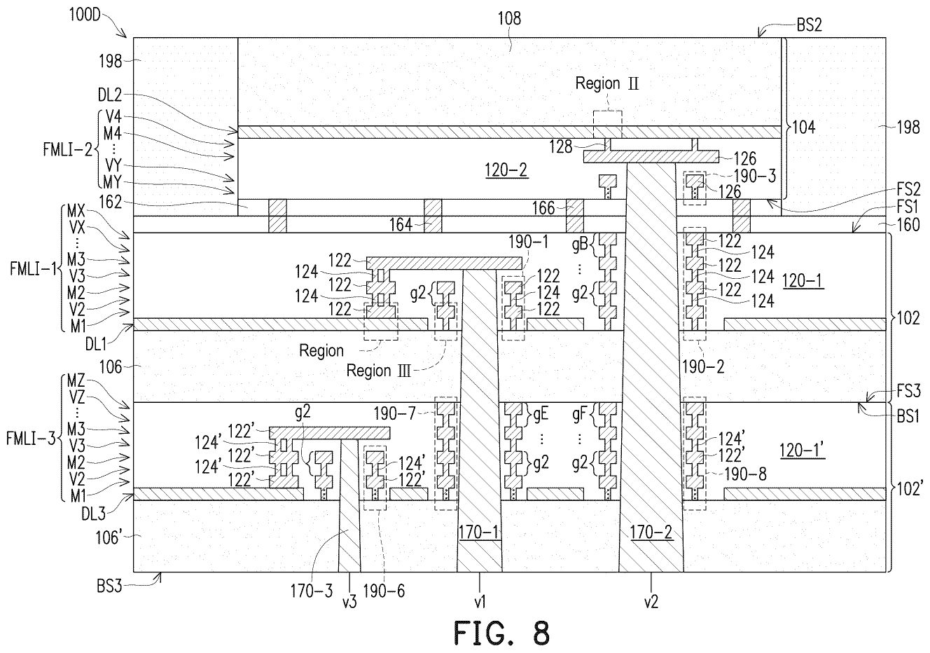

FIG. 1 is a cross-sectional view of a stacked chip structure 100A, in portion or entirety, having an improved power delivery structure, according to various aspects of the present disclosure. FIG. 2A is a cross-sectional view of a stacked chip structure 100B, in portion or entirety, having another improved power delivery structure, according to various aspects of the present disclosure. FIG. 2B is a cross-sectional view of a stacked chip structure 100C, in portion or entirety, having another improved power delivery structure, according to various aspects of the present disclosure. FIG. 8 is a cross-sectional view of a stacked chip structure 100D, in portion or entirety, having an improved power delivery structure, according to various aspects of the present disclosure. Stacked chip structure 100B is similar in many respects to stacked chip structure 100A, stacked chip structure 100C is similar in many respects to stacked chip structure 100B, and stacked chip structure 100D is similar in many respects to stacked chip structure 100A. Accordingly, similar features in FIG. 8, FIG. 2B, FIG. 2A, and FIG. 1 are identified by the same reference numbers for clarity and simplicity. FIG. 3A, FIG. 3B, FIG. 3C, FIG. 3D, and FIG. 3E are enlarged, cross-sectional views of portions of stacked chip structures 100A-100D, according to various aspects of the present disclosure. FIG. 4A, FIG. 4B, and FIG. 4C are top views of guard rings that may be formed around a through via, in portion or entirety, and that may be implemented in stacked chip structures 100A-100D, according to various aspects of the present disclosure. FIG. 5A is a plan view of the power delivery structure, in portion or entirety, of stacked chip structure 100B, according to various aspects of the present disclosure. FIG. 5B is another plan view of the power delivery structure, in portion or entirety, of stacked chip structure 100B, according to various aspects of the present disclosure. FIG. 6A is a plan view of the power delivery structure, in portion or entirety, of stacked chip structure 100A, according to various aspects of the present disclosure. FIG. 6B is a plan view of the power delivery structure, in portion or entirety, of stacked chip structure 100B, according to various aspects of the present disclosure. FIG. 7A, FIG. 7B, FIG. 7C, FIG. 7D, FIG. 7E, FIG. 7F, FIG. 7G, FIG. 7H, FIG. 7I, and FIG. 7J are plan views of power delivery structures, in portion or entirety, having various configurations, which may be implemented in stacked chip structures 100A-100D, according to various aspects of the present disclosure. FIG. 1, FIG. 2A, FIG. 2B, FIGS. 3A-3E, FIGS. 4A-4C, FIG. 5A, FIG. 5B, FIG. 6A, FIG. 6B, FIGS. 7A-7J, and FIG. 8 are discussed concurrently herein for ease of description and understanding. FIG. 1, FIG. 2A, FIG. 2B, FIGS. 3A-3E, FIGS. 4A-4C, FIG. 5A, FIG. 5B, FIG. 6A, FIG. 6B, FIGS. 7A-7J, and FIG. 8 have been simplified for the sake of clarity to better understand the inventive concepts of the present disclosure. Additional features may be added in the depicted stacked chip structures, and some of the features described below can be replaced, modified, or eliminated in other embodiments of the depicted stacked chip structures.

Referring to FIG. 1, stacked chip structure 100A includes chip stack having a chip 102 and a chip 104. Chip 104 is mounted on and vertically stacked over chip 102. The chip stack may form an IC (and/or semiconductor) package, or a portion thereof. Chip 102 and chip 104 may be a bottom chip and a top chip, respectively, of the chip stack and/or IC package. Chip 102 and chip 104 each include at least one functional IC, such as an IC configured to perform a logic function, a memory function, a digital function, an analog function, a mixed signal function, a radio frequency (RF) function, an input/output (I/O) function, a communications function, a power management function, other function, or combinations thereof. In some embodiments, chip 102 and chip 104 provide the same function (e.g., both may be central processing units (CPUs)). In some embodiments, chip 102 and chip 104 provide different functions (e.g., one may be a CPU, while the other one may be a graphics processing unit (GPU) or a static random-access memory (SRAM)). In some embodiments, chip 102 and/or chip 104 is a system-on-chip (SoC), which generally refers to a single chip and/or monolithic die having multiple functions. In some embodiments, the SoC is a single chip having an entire system, such as a computer system, fabricated thereon. In some embodiments, the IC package provides a system on integrated chip (SoIC). The SoIC may have a multichip, hybrid node design, and chip 102 and chip 104 may have different functions (e.g., CPU, GPU, RF, SRAM, etc.) and be fabricated according to different process nodes (e.g., 3 nm (N3), N5, N65, 0.13-micron (μm) (C013), etc.), where the functions and the process nodes may be selected based on design specifications, such as power, performance, area, and cost (PPAC) specifications.

Chip 102 and chip 104 may each include a device layer, such as a device layer DL1 and a device layer DL2, respectively. Device layer DL1 includes circuitry fabricated on and/or over a frontside of a substrate 106, and device layer DL2 includes circuitry fabricated on and/or over a frontside of a substrate 108. The circuitry may be fabricated by front end-of-line (FEOL) processing. Device layer DL1 and/or device layer DL2 may include various device components, such as a semiconductor substrate, doped wells (e.g., n-wells and/or p-wells), isolation features (e.g., shallow trench isolation (STI) structures and/or other suitable isolation structures), gates (e.g., a gate stack having a gate electrode and a gate dielectric), gate spacers along sidewalls of the gates, source/drains (e.g., epitaxial source/drains), other suitable device components/features, or combinations thereof. In some embodiments, device layer DL1 and/or device layer DL2 includes planar transistors. A channel of a planar transistor may be formed in a semiconductor substrate (e.g., substrate 106 and/or substrate 108) between respective source/drains, and a respective gate of the planar transistor may be disposed on the channel (e.g., on a portion of the semiconductor substrate in which the channel forms between the source/drains). In some embodiments, device layer DL1 and/or device layer DL2 includes non-planar transistors having channels formed in respective semiconductors fin that extend from a semiconductor substrate and between respective source/drains on/in the semiconductor fins, where a respective gate is disposed on and wraps a channel of a respective semiconductor fin (i.e., the non-planar transistors are fin-like field effect transistors (FinFETs)). In some embodiments, device layer DL1 and/or device layer DL2 includes non-planar transistors having channels formed in semiconductor layers suspended over a semiconductor substrate and extending between respective source/drains, where a respective gate is disposed on and at least partially surrounds respective channels (i.e., the non-planar transistors are gate-all-around (GAA) transistors and/or fork-sheet transistors). The transistors of device layer DL1 and/or device layer DL2 may be configured as planar transistors and/or non-planar transistors depending on design requirements. In some embodiments, device layer DL1 and/or device layer DL2 includes stacked transistors, such as complementary field effect transistors (CFETs) and/or other stacked transistors.

Device layer DL1 and/or device layer DL2 may include various passive electronic devices and/or active electronic devices, such as resistors, capacitors, inductors, diodes, p-type FETs (PFETs), n-type FETs (NFETs), metal-oxide semiconductor (MOS) FETs (MOSFETs), complementary MOS (CMOS) transistors, bipolar junction transistors (BJTs), laterally diffused MOS (LDMOS) transistors, high voltage transistors, high frequency transistors, other suitable devices and/or components, or combinations thereof. The various electronic devices may be configured to provide functionally distinct regions of an IC, such as a logic region (i.e., a core region), a memory region, an analog region, a peripheral region (e.g., an I/O region), a dummy region, other suitable region, or combinations thereof. The logic region may be configured with standard cells, each of which may provide a logic device and/or a logic function, such as an inverter, an AND gate, a NAND gate, an OR gate, a NOR gate, a NOT gate, an XOR gate, an XNOR gate, other suitable logic device, or combinations thereof. The memory region may be configured with memory cells, each of which may provide a storage device and/or storage function, such as flash memory, non-volatile random-access memory (NVRAM), SRAM, dynamic random-access memory (DRAM), other volatile memory, other non-volatile memory, other suitable memory, or combinations thereof. In some embodiments, memory cells and/or logic cells include transistors and interconnect structures that may combine to provide storage devices/functions and logic devices/functions, respectively.

Referring to FIG. 3A, an enlarged view of a Region I of stacked chip structure 100A is provided that depicts a portion of device features and/or device components of device layer DL1 of chip 102. In FIG. 3A, device layer DL1 includes various transistors, such as a transistor T1 and a transistor T2, formed over/on substrate 106. Transistor T1 and transistor T2 each include a respective gate structure 110 disposed between respective source/drains 112 (e.g., epitaxial source/drains), which may be disposed in substrate 106, and transistor T1 and transistor T2 each have a respective channel that extends between respective source/drains 112. Gate structures 110 may include a gate stack (e.g., a gate electrode disposed over a gate dielectric) and gate spacers disposed along sidewalls of the gate stack, and substrate 106 may be a semiconductor substrate (e.g., a silicon substrate). Device layer DL1 may further include isolation structures 114, such as STI structures, that separate and/or electrically isolate transistor T1 and/or transistor T2 from other transistors or devices of device layer DL1. Device layer DL1 may further include an insulator layer, such as a dielectric layer 116, disposed over substrate 106, and gate structures 110 of transistor T1 and transistor T2 may be disposed in dielectric layer 116. In some embodiments, dielectric layer 116 has a multilayer structure and may include, for example, an interlayer dielectric (ILD) layer and/or a contact etch stop layer (CESL).

Referring to FIG. 3B, an enlarged view of a Region II of stacked chip structure 100A is provided that depicts a portion of device features and/or device components of device layer DL2 of chip 104. In FIG. 3B, device layer DL2 also includes various transistors, such as a transistor T3 and a transistor T4, formed over/on substrate 108. Transistor T3 and transistor T4 each include a respective gate structure 118 disposed between respective source/drains 120 (e.g., epitaxial source/drains), which are disposed in substrate 108, and transistor T3 and transistor T4 each have a respective channel that extends between respective source/drains 120 in substrate 108. Gate structures 118 may include a gate stack (e.g., a gate electrode disposed over a gate dielectric) and gate spacers disposed along sidewalls of the gate stack, and substrate 108 may be a semiconductor substrate. Device layer DL2 may further include isolation structures 122 that separate and/or electrically isolate transistor T3 and/or transistor T4 from other transistors or devices of device layer DL2. Device layer DL2 may further include an insulator layer, such as a dielectric layer 124, disposed over substrate 108, and gate structures 118 of transistor T3 and transistor T4 may be disposed in dielectric layer 124. In some embodiments, dielectric layer 124 has a multilayer structure and may include, for example, an ILD layer and/or a CESL.

Referring to FIG. 1, FIG. 3A, and FIG. 3B, chip 102 and chip 104 may each include a frontside multilayer interconnect (FMLI) structure, such as an FMLI-1 structure over a frontside of substrate 106 and an FMLI-2 structure over a frontside of substrate 108, respectively. FMLI-1 structure and FMLI-2 structure each include a combination of dielectric layers (depicted as an insulation layer 120-1 and an insulation layer 120-2) and electrically conductive layers (e.g., patterned metal layers, each of which may be a group of metal lines, metal vias, metal contacts, or combinations thereof arranged in a desired pattern) that combine to form interconnect (routing) structures. The interconnect structures may include vertically oriented electrically conductive features, such as metal contacts and/or metal vias, that connect horizontally oriented electrically conductive features, such as metal lines, in different layers/levels (or different planes) of a respective FMLI structure. In some embodiments, the routing structures of FMLI-1 structure route electrical signals between devices and/or components of device layer DL-1, FMLI-1 structure, chip 102, chip 104, FMLI-2 structure, external devices and/or components, or combinations thereof. In some embodiments, the routing structures of FMLI-2 structure route electrical signals between devices and/or components of device layer DL-2, FMLI-2 structure, chip 104, chip 102, FMLI-1 structure, external devices and/or components, or combinations thereof. In some embodiments, FMLI-1 structure and/or of FMLI-2 structure distribute electrical signals (e.g., clock signals, voltage signals, ground signals, etc.) to the devices/components of chip 102, chip 104, external devices and/or components, or combinations thereof.

FMLI-1 structure includes a device-level contact layer and/or via layer (collectively referred to as a via zero layer (V0 level)), a metal zero layer (M0 level), a via one layer (V1 level), a metal one layer (M1 level), a via two layer (V2 level), a metal two layer (M2 level), and so on to a via (X−1) layer (V(X−1) level), a metal (X−1) layer (M(X−1) level), a via X layer (VX level), and a metal X layer (MX level), where X is an integer (e.g., from 2 to 10). Each level of FMLI-1 structure may include conductive features, such as metal lines 122 or metal vias 124, disposed in a portion of insulation layer 120-1. Metal lines 122 of M0 level, M1 level, M2 level, . . . M(X−1) level, and MX level may be referred to as M0 lines, M1 lines, M2 lines, . . . M(X−1) lines, and MX lines, respectively. Metal vias 124 of V0 level, V1 level, V2 level, . . . V(X−1) level, and VX level may be referred to as V0 vias, V1 vias, V2 vias, . . . V(X−1) vias, and VX vias, respectively. Each metal via 124 may physically and/or electrically connect an underlying metal line 122 (e.g., a respective M1 line) and an overlying metal line 122 (e.g., a respective M2 line), an underlying device-level contact (e.g., a source/drain contact) and an overlying metal line 122 (e.g., a respective M0 line), or an underlying device feature (e.g., a gate and/or a source/drain) and an overlying metal line 122 (e.g., a respective M0 line).

FMLI-2 structure may be similar to FMLI-1 structure. For example, FMLI-2 structure includes a respective V0 level, a respective M0 level, a respective V1 level, a respective M1 level, a respective V2 level, a respective M2 level, and so on to a via (Y−1) layer (V(Y−1) level), a metal (Y−1) layer (M(Y−1) level), a via Y layer (VY level), and a metal Y layer (MY level), where Y is an integer (e.g., from 2 to 10). Y may be the same or different than X. Each level of FMLI-2 structure may include conductive features, such as metal lines 126 or metal vias 128, disposed in a portion of insulation layer 120-2. Metal lines 126 of M0 level, M1 level, M2 level, . . . M(Y−1) level, and MY level may be referred to as M0 lines, M1 lines, M2 lines, . . . M(Y−1) lines, and MY lines, respectively. Metal vias 128 of V0 level, V1 level, V2 level, . . . V(Y−1) level, and VY level may be referred to as V0 vias, V1 vias, V2 vias, . . . V(Y−1) vias, and VY vias, respectively. Each metal via 128 may physically and/or electrically connect an underlying metal line 126 (e.g., a respective M1 line) and an overlying metal line 126 (e.g., a respective M2 line), an underlying device-level contact (e.g., a source/drain contact) and an overlying metal line 126 (e.g., a respective M0 line), or an underlying device feature (e.g., a gate and/or a source/drain) and an overlying metal line 126 (e.g., a respective M0 line).

Device level (e.g., a bottommost level) of FMLI-1 structure (e.g., V0 level) may be fabricated by middle-of-line (MOL) processing, and additional levels of FMLI-1 structure (e.g., M0 level and up) may be fabricated by back-end-of-line (BEOL) processing. V0 level of chip 102 may thus be referred to as an MOL structure, and M0 level and up of chip 102 may be referred to as a BEOL structure. Referring again to FIG. 3A, Region I may further include at least a portion of V0 level, M0 level, and V1 level of chip 102. V0 level may include dielectric layer 116, a dielectric layer 130 over dielectric layer 116, source/drain contacts (MDs) in dielectric layer 116, source/drain vias (VDs) in dielectric layer 130, and gate contacts (VGs) (e.g., a gate contact 132) in dielectric layer 130. Gate contact 132 connects a respective gate structure 110 (e.g., a gate electrode thereof) to a respective metal line 122 of M0 level of FMLI-1 structure. M0 level may include a dielectric layer 134 having metal lines 122 disposed therein. V1 level may include a dielectric layer 136 having metal vias 124 disposed therein. M1 level may include a dielectric layer 138 having metal lines 122 disposed therein. Dielectric layer 116, dielectric layer 130, dielectric layer 134, dielectric layer 136, and dielectric layer 138 may form a portion of insulation layer 120-1. V0 level may include an MD level formed by source/drain contacts and a VD/VG level formed by source/drain vias and/or gate contacts.

Device level of FMLI-2 structure (e.g., V0 level) may be fabricated by MOL processing, and additional levels of FMLI-2 structure (e.g., M0 level and up) may be fabricated by BEOL processing. V0 level of chip 104 may thus be referred to as an MOL structure, and M0 level and up of chip 104 may be referred to as a BEOL structure. Referring again to FIG. 3B, Region II may further include at least a portion of V0 level, M0 level, V1 level, M1 level, V2 level, M2 level, V3 level, and M3 level of chip 104. For example, V0 level may include dielectric layer 124, a dielectric layer 140 over dielectric layer 124, source/drain contacts (e.g., a source/drain contact 142) in dielectric layer 124, source/drain vias (e.g., a source/drain via 144) in dielectric layer 140, and gate contacts in dielectric layer 140. Source/drain contact 142 connects a respective source/drain 120 to source/drain via 144, and source/drain via 144 connects source/drain contact 142 to a respective metal line 126 of M0 level of FMLI-2 structure. M0 level may include a dielectric layer 146 having metal lines 126 disposed therein; V1 level may include a dielectric layer 148 having metal vias 128 disposed therein; M1 level may include a dielectric layer 150 having metal lines 126 disposed therein; V2 level may include a dielectric layer 152 having metal vias 128 disposed therein; M2 level may include a dielectric layer 154 having metal lines 126 disposed therein; V3 level may include a dielectric layer 156 having metal vias 128 disposed therein; and M3 level may include a dielectric layer 158 having metal lines 126 disposed therein. Dielectric layer 124, dielectric layer 140, dielectric layer 146, dielectric layer 148, dielectric layer 150, dielectric layer 152, dielectric layer 154, dielectric layer 156, and dielectric layer 158 may form a portion of insulation layer 120-2.

Referring back to FIG. 1, chip 102 and chip 104 are stacked and attached (bonded) front-to-front and/or face-to-face. For example, chip 102 has a frontside FS1 formed by FMLI-1 structure and a backside BS1 formed by substrate 106 (e.g., a backside thereof), chip 104 has a frontside FS2 formed by FMLI-2 structure and a backside BS2 formed by substrate 108 (e.g., a backside thereof), and FMLI-1 structure is attached (bonded) to FLMI-2 structure. Face-to-face bonding of chip 102 and chip 104 may be achieved by dielectric-to-dielectric bonding (e.g., oxide-to-oxide bonding), metal-to-metal bonding (e.g., copper-to-copper bonding), metal-to-dielectric bonding (e.g., copper-to-oxide bonding), other type of bonding, or combinations thereof. In the depicted embodiment, chip 104 is mounted on chip 102 using hybrid bonding (i.e., using both metal-to-metal bonding and nonmetal-to-nonmetal bonding), and chip 104 may be electrically connected to chip 102 via the hybrid bonding. For example, chip 102 and chip 104 may each include a bonding structure that includes a non-metal portion (e.g., a bonding layer 160 and a bonding layer 162, respectively) and a metal portion (e.g., bonding pads 164 and bonding pads 166, respectively). Bonding pads 164 are disposed in bonding layer 160, and bonding pads 166 are disposed in bonding layer 162. In some embodiments, bonding layer 160 and bonding layer 162 are polymer layers including, for example, benzocyclobutene (BCB), polyimide (PI), polybenzoxazole (PBO), other polymer material, or combinations thereof. In some embodiments, bonding pads 164 and bonding pads 166 include copper, aluminum, other suitable metal, alloys thereof, or combinations thereof. In some embodiments, bonding layer 160, bonding layer 162, bonding pads 164, bonding pads 166, or combinations thereof have multilayer structures. Bonding pads 164 may be connected to interconnect structures of FMLI-1 structure, and bonding pads 164 may be connected to interconnect structures of FMLI-2 structure. For example, one or more bonding pads 164 may be connected to respective metal lines 122 of MX level of FMLI-1 structure, and one or more bonding pads 166 may be connected to respective metal lines 126 of MY level of FMLI-2 structure. In some embodiments, chip interconnection structures (e.g., a respective bonding pad 164 and a respective bonding pad 166) may electrically connect FMLI-1 structure and FMLI-2 structure.

Stacked chip structure 100A further includes a power delivery structure for directly delivering power to each chip, such as chip 102 and chip 104. For example, the power delivery structure of stacked chip structure 100A includes a through substrate via (TSV) 170-1 and a TSV 170-2 (also referred to as through vias, through silicon vias, through semiconductor vias, or combinations thereof). TSV 170-1 is electrically connected to device layer DL1 via FMLI-1 structure, and TSV 170-2 is electrically connected to device layer DL2 via FMLI-2 structure. For example, TSV 170-1 is connected to a respective metal line 122 of FMLI-1 structure (e.g., of M3 level thereof), which is connected to device layer DL1 (e.g., a transistor thereof, such as transistor T1 and/or transistor T2), and TSV 170-2 is connected to a respective metal line 126 of FMLI-2 structure (e.g., of M4 level thereof), which is connected to device layer DL2 (e.g., a transistor thereof, such as transistor T3 and/or transistor T4). TSV 170-1 is further electrically connected to a voltage v1, which may be generated and/or provided by a power supply source, and TSV 170-2 is further electrically connected to a voltage v2, which may be generated and/or provided by a power supply source. Accordingly, TSV 170-1 may deliver and/or supply power to devices and/or device components of device layer DL1, and TSV 170-2 may deliver and/or supply power to devices and/or device components of device layer DL2.

In such embodiments, TSV 170-1 and TSV 170-2 deliver power directly to chip 102 and chip 104, respectively, without an intermediate connection, such as the chip bonding structure. For example, TSV 170-2 is connected directly to FMLI-2 structure, instead of being connected to FMLI-2 structure through a hybrid chip bond (e.g., a connection formed by a respective bonding pad 164 and a respective bonding pad 166), and TSV 170-1 is connected directly to FMLI-1 structure. Eliminating the intermediate connection between TSV 170-2 and FMLI-2 structure (and/or between TSV 170-1 and FMLI-1 structure) may reduce resistance and/or capacitance associated with the power delivery route to chip 104 (and/or the power delivery route to chip 102), thereby reducing RC delay. Further, eliminating the intermediate connections (e.g., chip connections/bonds) between the power-delivery TSVs and the FMLI structures decreases IC design constraints and improves IC design flexibility. For example, since the power-delivery TSVs do not need to land on and/or connect to the chip bonds/connections to facilitate power delivery, spacing between the power-delivery TSVs (i.e., TSV pitch) is less (and/or not) constrained by spacing between the chip bonds/connections (i.e., chip bond pitch), and TSV pitch may be less than or greater than the chip bond pitch to optimize area utilization. In other words, the power-delivery TSVs may be freely placed in the disclosed stacked chip structures without the need to align the power-delivery TSVs with the chip bonds/connection. In some embodiments, spacing between power-delivery TSVs may be reduced, thereby reducing area consumed by the power delivery structure. Providing each chip with a dedicated power-delivery TSV also eliminates the need for additional routing/interconnections between the power-delivery TSVs and the chips, thereby reducing IC design and fabrication complexity. The dedicated power-delivery TSVs may further improve power delivery efficiency by reducing a length and/or complexity of power-delivery paths to the chips.

Referring to FIG. 3C, an enlarged view of TSV 170-1 is provided, according to some embodiments. TSV 170-1 is disposed in chip 102, but not chip 104. For example, TSV 170-1 is disposed in and extends through substrate 106 and into insulation layer 120-1 to M3 level of FMLI-1 structure. In some embodiments, TSV 170-1 may extend to a different level of FMLI-1 structure, such as to a respective metal line 122 of one of M4 level to MX level. In some embodiments, such as depicted, an insulation layer 172 is disposed over backside BS1 of substrate 106, and TSV 170-1 may be disposed in and extend through insulation layer 172. In some embodiments, insulation layer 172 includes a dielectric material. Insulation layer 172 may have a multilayer structure, such as a dielectric layer 174 and a dielectric layer 176. Dielectric layer 174 and dielectric layer 176 have different compositions. For example, dielectric layer 174 may be an oxide layer, and dielectric layer 176 may be a nitride layer.

TSV 170-1 may include an electrically conductive core 182A, a barrier layer 184A, and a dielectric liner 186A. In some embodiments, electrically conductive core 182A is wrapped by barrier layer 184A, and barrier layer 184A is disposed along a bottom and sidewalls of electrically conductive core 182A. Barrier layer 184A is between dielectric liner 186A and electrically conductive core 182A, and dielectric liner 186A is between barrier layer 184A and substrate 106, insulation layer 120-1, and insulation layer 172. Thus, a bottom of TSV 170-1 may be formed by electrically conductive core 182A, barrier layer 184A, and dielectric liner 186A, a top of TSV 170-1 may be formed by barrier layer 184A and dielectric liner 186A, and sidewalls of TSV 170-1 may be formed by dielectric liner 186A.

Referring to FIG. 3D, an enlarged view of TSV 170-2 is provided, according to some embodiments. TSV 170-2 is disposed in chip 102 and chip 104. For example, TSV 170-2 is disposed in and extends through substrate 106, insulation layer 120-1, the chip bonding structure (e.g., bonding layer 160 and bonding layer 162 thereof), and into insulation layer 120-2 to the M4 level of FMLI-2 structure. In some embodiments, TSV 170-2 may extend to a different level of FMLI-2 structure, such as to a respective metal line 126 of one of M5 level to MY level. In some embodiments, such as depicted, TSV 170-2 may also be disposed in and extend through insulation layer 172 (e.g., dielectric layer 174 and dielectric layer 176 thereof).

TSV 170-2 may include an electrically conductive core 182B, a barrier layer 184B, and a dielectric liner 186B. In some embodiments, electrically conductive core 182B is wrapped by barrier layer 184B, and barrier layer 184B is disposed along a bottom and sidewalls of electrically conductive core 182B. Barrier layer 184B is between dielectric liner 186B and electrically conductive core 182B, and dielectric liner 186B is between barrier layer 184B and insulation layer 172, substrate 106, insulation layer 120-1, bonding layer 160, bonding layer 162, and insulation layer 120-2. Thus, a bottom of TSV 170-2 may be formed by electrically conductive core 182B, barrier layer 184B, and dielectric liner 186B, a top of TSV 170-2 may be formed by barrier layer 184B and dielectric liner 186B, and sidewalls of TSV 170-2 may be formed by dielectric liner 186B.

Electrically conductive core 182A and electrically conductive core 182B (which may also be referred to as pillars, metal pillars, bulk metal layers, metal fill layers, conductive plugs, metal plugs, etc.) each include an electrically conductive material, such as aluminum, copper, titanium, tantalum, tungsten, ruthenium, cobalt, iridium, palladium, platinum, nickel, tin, gold, silver, other suitable metals, alloys thereof, silicides thereof, or combinations thereof. For example, electrically conductive core 182A and electrically conductive core 182B may include copper (i.e., copper plugs), tungsten (i.e., tungsten plugs), or polysilicon (i.e., polysilicon plugs). In some embodiments, electrically conductive core 182A and electrically conductive core 182B include different electrically conductive materials. Electrically conductive core 182A and/or electrically conductive core 182B may have a multilayer structure. For example, an electrically conductive core may include a seed layer and a metal plug, where the seed layer is between the metal plug and a respective barrier layer. The seed layer may include copper, tungsten, other suitable metals, alloys thereof, or combinations thereof. In some embodiments, barrier layer 184A and/or barrier layer 184B are the seed layers of the TSVs.

Barrier layer 184A and barrier layer 184B may include titanium, titanium alloy (e.g., TiN and/or TiC), tantalum, tantalum alloy (e.g., TaN and/or TaC), aluminum, aluminum alloy (e.g., AlON and/or Al₂O₃), other suitable barrier material (e.g., a material that can prevent diffusion of metal constituents from an electrically conductive core into substrate 106, insulation layer 120-1, insulation layer 120-2, bonding layer 160, bonding layer 162, insulation layer 172, or combinations thereof), or combinations thereof. Dielectric liner 186A and dielectric liner 186B include a dielectric material, such as silicon oxide, silicon nitride, silicon carbonitride, other suitable dielectric material, or combinations thereof. In some embodiments, barrier layer 184A and/or barrier layer 184B have a multilayer structure. In some embodiments, dielectric liner 186A and/or dielectric liner 186B have a multilayer structure.

Referring to FIG. 1, FIG. 3C, and FIG. 3D, TSV 170-1 has a diameter D1 (and/or a width) (e.g., along the x-direction and/or the y-direction) and a height H1 (e.g., along the z-direction), and TSV 170-2 has a diameter D2 (and/or a width) (e.g., along the x-direction and/or the y-direction) and a height H2 (e.g., along the z-direction). Diameter D2 is greater than diameter D1, and height H2 is greater than height H1. Power delivery TSVs with different depths thus have different critical dimensions (CDs) (e.g., diameter increases as height increases), and a diameter of a power delivery TSV to a top die (e.g., TSV 170-2 to chip 104) is greater than a diameter of a power delivery TSV to a bottom die (e.g., TSV 170-1 to chip 102). In some embodiments, each of diameter D1 and diameter D2 is less than about 15 μm. For example, diameter D1 may be about 0.5 μm to about 10 μm, and diameter D2 may be about 2 μm to about 15 μm. Power delivery TSVs of stacked chip structure 100A have about the same aspect ratio. For example, an aspect ratio R1 of height H1 to diameter D1 is about the same as an aspect ratio R2 of height H2 to diameter D2 (i.e., AR1 (=H1/D1)=AR2 (=H2/D2)). In some embodiments, each of aspect ratio R1 and aspect ratio R2 is about 5 to about 20. In some embodiments, aspect ratio R1 and aspect ratio R2 are about 10. For example, diameter D1 may be about 2 μm, height H1 may be about 20 μm, diameter D2 may be about 3 μm, and height H2 may be about 30 μm. In another example, diameter D1 may be about 4.5 μm, height H1 may be about 45 μm, diameter D2 may be about 8 μm, and height H2 may be about 80 μm. In some embodiments, aspect ratio R1 and aspect ratio R2 are adjusted/tuned to provide chip 102 and chip 104 with substantially the same contact resistance (R_{c}). In some embodiments, diameter D1 and diameter D2 are adjusted/tuned to provide chip 102 and chip 104 with substantially the same contact resistance. In some embodiments, height H1 and height H2 are adjusted/tuned to provide chip 102 and chip 104 with substantially the same contact resistance.

In some embodiments, TSV 170-1 and/or TSV 170-2 have a circular shape in a top view (FIGS. 4A-4C), and TSV 170-1 and/or TSV 170-2 may be a cylindrical structure. TSV 170-1 and/or TSV 170-2 may have different shapes in a top view, such as a square shape, a rhombus shape, a trapezoidal shape, a hexagonal shape, an octagonal shape, or other suitable shape. In some embodiments, diameter D1 varies along height H1, and/or diameter D2 varies along height H2. For example, TSV 170-1 and TSV 170-2 may have a tapered sidewall profile (i.e., tapered sidewalls), such as depicted, such that diameter D1 increases along height H1 from top to bottom and diameter D2 increases along height H2 from top to bottom. In some embodiments, diameter D1 decreases along height H1 from top to bottom and/or diameter D2 decreases along height H2 from top to bottom. The present disclosure contemplates TSV 170-1 and/or TSV 170-2 having various sidewall profile configurations, such that TSV 170-1 may have various variations of diameter D1 along its height H1 and TSV 170-2 may have various variations of diameter D2 along its height H2. For example, TSV 170-1 and TSV 170-2 may have a vertical sidewall profile (i.e., substantially straight sidewalls), such that diameter D1 may be substantially the same along height H1 from top to bottom and diameter D2 may be substantially the same along height H2 from top to bottom. In another example, TSV 170-1 and TSV 170-2 may have different sidewall profiles (e.g., one tapered, one vertical).

In stacked chip structure 100A, each power delivery TSV has a corresponding, respective guard ring. For example, a guard ring 190-1 is spaced apart from and around TSV 170-1, and a guard ring 190-2 is spaced apart from and around TSV 170-2. Insulation layer 120-1 may fill spacing between guard ring 190-1 and TSV 170-1, and insulation layer 120-1 may fill spacing between guard ring 190-2 and TSV 170-2. Referring to FIGS. 4A-4C, from a top view (or a bottom view), guard ring 190-1 may be a circular ring (FIG. 4A), a square ring (FIG. 4B), an octagonal ring (FIG. 4C), a hexagonal ring, or other suitable shaped ring around TSV 170-1. Guard ring 190-2 may also be a circular ring, a square ring, an octagonal ring, a hexagonal ring, or other suitable shaped ring around TSV 170-2. In the depicted embodiment, guard ring 190-1 and guard ring 190-2 extend continuously around TSV 170-1 and TSV 170-2, respectively. In some embodiments, guard ring 190-1 and guard ring 190-2 are discontinuous around TSV 170-1 and TSV 170-2, respectively. For example, guard ring 190-1 and/or guard ring 190-2 may be formed by discrete segments that combine to form a ring around its respective TSV.

Referring to FIG. 1 and FIG. 3E, guard ring 190-1 and guard ring 190-2 may each be formed from a portion of FMLI-1 structure. In some embodiments, each of guard ring 190-1 and guard ring 190-2 has an interconnect structure stack disposed in and extending through insulation layer 120-1. The interconnect structure stack of guard ring 190-1 may include a guard ring zero layer (g0 level), a guard ring one layer (g1 level), and a guard ring two layer (g2 level), and the interconnect structure stack of guard ring 190-2 may include a g0 level, a g1 level, and so on to a guard ring g(B−1) layer (g(B−1) level), and a guard ring B layer (gB level), where B is an integer (e.g., from 2 to 10). Each guard ring level may be formed from one or more interconnect structures, each of which may include a respective metal line 122 and a respective metal via 124. For example, g2 level of both guard ring 190-1 and guard ring 190-2 may include a respective metal line 122 of M2 level disposed on a respective metal via 124 of V2 level.

Referring to FIG. 3E, an enlarged view of a Region III of stacked chip structure 100A is provided of a portion of guard ring 190-1, according to some embodiments. In such embodiment, guard ring 190-1 may be connected to a respective source/drain 112 in substrate 106. For example, the interconnect structure stack of guard ring 190-1 may include a device-level interconnect structure (g0 level) disposed on the respective source/drain 112 and an interconnect structure (g1 level) disposed on the device-level interconnect structure. The g0 level interconnect structure may include a respective source/drain contact 142 in dielectric layer 116, a respective source/drain via 144 in dielectric layer 130, and a respective metal line 122 in dielectric layer 134. The g1 level interconnect structure may include a respective metal via 124 in dielectric layer 136 and a respective metal line 122 in dielectric layer 138.

The interconnect structure stacks may have more or less interconnect structures, and the interconnect structure stacks may have a number of interconnect structures that is more than, less than, or the same as a number of levels of FMLI-1 structure. In the depicted embodiment, guard ring 190-1 and guard ring 190-2 have different heights, and guard ring 190-1 and guard ring 190-2 have uniform heights. For example, guard ring 190-1 extends from substrate 106 to M2 level on both sides of TSV 170-1, and guard ring 190-2 extends from substrate 106 to MX level on both sides of TSV 170-2. In such example, TSV 170-1 may extend vertically beyond a top of guard ring 190-1 (e.g., to M3 level), and TSV 170-2 may extend vertically beyond a top of guard ring 190-2 (e.g., to chip 104). In some embodiments, guard ring 190-1 is not connected to TSV 170-1, and guard ring 190-2 is not connected to TSV 170-2. For example, metal line 122 of M3 level extends laterally over a top of guard ring 190-1, guard ring 190-1 does not include metal vias 124 in V3 level, and guard ring 190-1 (e.g., topmost metal lines 122 thereof (in M2 level)) are not connected to metal line 122 of M3 level extending thereover.

In some embodiments, power delivery TSVs that extend through and/or into more than one chip may have a corresponding, respective guard ring in each chip. For example, in chip 104, a guard ring 190-3 may be spaced apart from and around TSV 170-2. Insulation layer 120-2 may fill spacing between guard ring 190-3 and TSV 170-2. Guard ring 190-3 may also be a circular ring, a square ring, an octagonal ring, a hexagonal ring, or other suitable shaped ring around TSV 170-2. In the depicted embodiment, guard ring 190-3 extends continuously around TSV 170-2. In some embodiments, guard ring 190-3 is discontinuous around TSV 170-2. In some embodiments, guard ring 190-3 has an interconnect structure stack disposed in and extending through insulation layer 120-2. In the depicted embodiment, where TSV 170-2 lands on M4 level, the interconnect structure stack of guard ring 190-3 may include a g5 level, and so on to a guard ring g(C−1) layer (g(C−1) level), and a guard ring C layer (gC level), where C is an integer (e.g., 5 to 10). Each guard ring level may be formed from one or more interconnect structures, each of which may include a respective metal line 126 and a respective metal via 128. Similar to guard ring 190-1 and guard ring 190-2, guard ring 190-3 has a uniform height.

In some embodiments, guard ring 190-1 and/or guard ring 190-2 are electrically connected to a voltage. In some embodiments, guard ring 190-1 and/or guard ring 190-2 are electrically connected to an electrical ground. In some embodiments, guard ring 190-1 and guard ring 190-2 are configured to electrically insulate TSV 170-1 and TSV 170-2, respectively, from device regions of chip 102. For example, TSV 170-1 may be disposed between device regions of device layer DL-1 (e.g., having transistors) and portions of FMLI-1 structure thereover and connected thereto, guard ring 190-1 may be disposed between TSV 170-1 and these device regions, and guard ring 190-1 may electrically insulate TSV 170-1 from these device regions. TSV 170-2 may also be disposed between device regions of device layer DL-1 and portions of FMLI-1 structure thereover and connected thereto, guard ring 190-2 may be disposed between TSV 170-2 and these device regions, and guard ring 190-2 may electrically insulate TSV 170-2 from these device regions. In some embodiments, guard ring 190-3 is configured to electrically insulate TSV 170-2 from device regions of chip 104. In some embodiments, guard ring 190-1, guard ring 190-2, guard ring 190-3, or combinations thereof absorb and/or reduce thermal stress and/or mechanical stress from, within, and/or around the TSVs. In some embodiments, guard ring 190-1, guard ring 190-2, guard ring 190-3, or combinations thereof provide structural support, integrity, reinforcement, or combinations thereof for the TSVs.

Stacked chip structure 100A may further include an encapsulant 198 (also referred to as a molding and/or a molding compound). Chip 104 and its corresponding bonding structure (e.g., bonding layer 162 having bonding pads 166 therein) may be disposed in and/or covered by encapsulant 198. For example, encapsulant 198 may circumferentially surround chip 104. In some embodiments, encapsulant 198 is disposed on edges/sidewalls of chip 104. In some embodiments, encapsulant 198 is disposed on chip 102 and/or its corresponding bonding structure (e.g., bonding layer 160 having bonding pads 164 therein). Encapsulant 198 may include an organic material, such as an epoxy-based material.

In stacked chip structure 100A, each power-delivery TSV to a respective chip has a corresponding, independent guard ring. In some embodiments, power-delivery TSVs may share a guard ring. For example, referring to FIG. 2A and FIG. 5A, stacked chip structure 100B is configured with a TSV cluster having a shared guard ring. For example, TSV 170-1 and TSV 170-2 share a guard ring 190-4, and TSV 170-1 extends to a respective metal line 122 of M4 level (which provides the TSV landing pad of chip 102), instead of M3 level. Guard ring 190-4 may be spaced apart from and around both TSV 170-1 and TSV 170-2. Insulation layer 120-1 may fill spacing between guard ring 190-4 and TSV 170-1, spacing between guard ring 190-4 and TSV 170-2, and spacing between TSV 170-1 and TSV 170-2. In stacked chip structure 100A (FIG. 1), a portion of guard ring 190-1 and a portion of guard ring 190-2 (e.g., two guard ring sides) are disposed in a portion/region of insulation layer 120-1 that extends from TSV 170-1 to TSV 170-2, and an active region (e.g., a region of device layer DL1 having transistors) may be between TSV 170-1 and TSV 170-2. In contrast, in stacked chip structure 100B, guard ring 190-4 forms an outer perimeter of a TSV region of chip 102, and a portion/region of insulation layer 120-1 that extends from TSV 170-1 to TSV 170-2 is free of any portion of a guard ring. In other words, a guard ring is not formed between TSV 170-1 and TSV 170-2 in stacked chip structure 100B. Guard ring 190-4 may be a circular ring, a square ring, an octagonal ring, a hexagonal ring, or other suitable shaped ring. In some embodiments, guard ring 190-4 extends continuously around TSV 170-1 and TSV 170-2 having different CDs (FIG. 5A), such as diameter D1 and diameter D2, respectively. In some embodiments, guard ring 190-4 extends continuously around TSV 170-1 and TSV 170-2 having the same CDs (FIG. 5B), such as diameter D2 (or diameter D1). In some embodiments, guard ring 190-4 is discontinuous.

Guard ring 190-4 may be formed from a portion of FMLI-1 structure. In some embodiments, guard ring 190-4 has an interconnect structure stack disposed in and extending through insulation layer 120-1. The interconnect structure stack of guard ring 190-4 may include a g0 level, a g1 level, and so on to a guard ring g(D-1) layer (g(D-1) level), and a guard ring D layer (gD level), where D is an integer (e.g., from 2 to 10). Each guard ring level may be formed from one or more interconnect structures, each of which may include a respective metal line 122 and a respective metal via 124. In contrast to guard ring 190-1 and guard ring 190-2, guard ring 190-4 has a varying height. For example, a side of guard ring 190-4 proximate TSV 170-1 extends from substrate 106 to M3 level (i.e., extends into insulation layer 120-1), while a side of guard ring 190-4 proximate TSV 170-2 extends from substrate 106 to MX level (i.e., extends through insulation layer 120-1). In such example, TSV 170-1 may extend vertically beyond a top of one side of guard ring 190-4 (e.g., at M3 level), but not a top of another side of guard ring 190-4 (e.g., at MX level), and TSV 170-2 may extend vertically beyond both sides of guard ring 190-4 to a TSV landing pad of chip 104 (e.g., a respective metal line 126 of M4 level or higher). In some embodiments, guard ring 190-4 is not connected to TSV 170-1 or TSV 170-2.

In some embodiments, guard ring 190-4 is connected to a doped region and/or a respective source/drain 112 in substrate 106. In some embodiments, guard ring 190-4 is electrically connected to a voltage. In some embodiments, guard ring 190-4 is electrically connected to an electrical ground. In some embodiments, guard ring 190-4 is configured to electrically insulate TSV 170-1 and TSV 170-2 from device regions of chip 102. In some embodiments, guard ring 190-4 absorbs and/or reduces thermal stress and/or mechanical stress from, within, and/or around the TSVs. In some embodiments, guard ring 190-4 provides structural support, integrity, reinforcement, or combinations thereof for its TSVs.

In some embodiments, power-delivery TSVs may share a guard ring that is configured around each power-delivery TSV. For example, referring to FIG. 2B, stacked chip structure 100C has a guard ring 190-5 that is shared by TSV 170-1 and TSV 170-2. Guard ring 190-5 may be spaced apart from and around both TSV 170-1 and TSV 170-2. Insulation layer 120-1 may fill spacing between guard ring 190-5 and TSV 170-1, between guard ring 190-5 and TSV 170-2, and between TSV 170-1 and TSV 170-2. Similar to guard ring 190-4, guard ring 190-5 forms an outer perimeter of a TSV region that includes both TSV 170-1 and TSV 170-2. In contrast to guard ring 190-4, guard ring 190-5 also includes an inner portion GI disposed in the portion/region of insulation layer 120-1 that extends from TSV 170-1 to TSV 170-2. With such configuration, guard ring 190-5 is also formed around each of TSV 170-1 and TSV 170-2, and a portion of guard ring 190-5 is between TSV 170-1 and TSV 170-2. In contrast to stacked chip structure 100A, one side (i.e., a shared side/wall formed by inner portion GI) of a guard ring is between TSV 170-1 and TSV 170-2, instead of two sides (i.e., a respective side/wall of guard ring 190-1 around TSV 170-1 and a respective side/wall of guard ring 190-2 around TSV 170-2). Guard ring 190-5 may be and/or form a circular ring, a square ring, an octagonal ring, a hexagonal ring, or other suitable shaped ring around both TSV 170-1 and TSV 170-2, around TSV 170-1, around TSV 170-2, or combinations thereof. In some embodiments, guard ring 190-5 extends continuously around both TSV 170-1 and TSV 170-2, around TSV 170-1, around TSV 170-2, or combinations thereof. In some embodiments, guard ring 190-5 is discontinuous around both TSV 170-1 and TSV 170-2, around TSV 170-1, around TSV 170-2, or combinations thereof. For example, guard ring 190-5 may be formed by discrete segments.

Guard ring 190-5 may be formed from a portion of FMLI-1 structure. In some embodiments, guard ring 190-5 has an interconnect structure stack disposed in and extending through insulation layer 120-1. The interconnect structure stack of guard ring 190-5 may include a g0 level, a g1 level, and so on to a guard ring g(D−1) layer (g(D−1) level), and a guard ring D layer (gD level), where D is an integer (e.g., from 2 to 10). Each guard ring level may be formed from one or more interconnect structures, each of which may include a respective metal line 122 and a respective metal via 124. Similar to guard ring 190-4, guard ring 190-5 has a varying height. For example, an outer side of guard ring 190-5 proximate TSV 170-1 extends from substrate 106 to M3 level (i.e., extends into insulation layer 120-1), while an outer side of guard ring 190-5 proximate TSV 170-2 extends from substrate 106 to MX level (i.e., extends through insulation layer 120-1). Further, an inner side of guard ring 190-5 that is between TSV 170-1 and TSV 170-2 (i.e., inner portion GI) extends from substrate 106 to M3 level. In some embodiments, the side of guard ring 190-5 that is between TSV 170-1 and TSV 170-2 is taller or shorter than the outer side of guard ring 190-5 proximate TSV 170-1. For example, the inner side of guard ring 190-5 may extend from substrate 106 to any of M4 level to MX level. In another example, the inner side of guard ring 190-5 may extend from substrate 106 to M2 level or lower. In stacked chip structure 100C, TSV 170-1 may extend vertically beyond a top of one outer side of guard ring 190-5 (e.g., at M3 level), but not a top of another outer side of guard ring 190-5 (e.g., at MX level), and TSV 170-2 may extend vertically beyond both outer sides of guard ring 190-5 to a TSV landing pad of chip 104 (e.g., a respective metal line 126 of M4 level or higher). Further, TSV 170-1 may or may not extend vertically beyond an inner side of guard ring 190-5, and TSV 170-2 may extend vertically beyond the inner side of guard ring 190-5. In some embodiments, guard ring 190-5 is not connected to TSV 170-1 or TSV 170-2.

In some embodiments, guard ring 190-5 is connected to a doped region and/or a respective source/drain 112 in substrate 106. In some embodiments, guard ring 190-5 is electrically connected to a voltage. In some embodiments, guard ring 190-5 is electrically connected to an electrical ground. In some embodiments, guard ring 190-5 is configured to electrically insulate TSV 170-1 and TSV 170-2 from device regions of chip 102. In some embodiments, guard ring 190-5 absorbs and/or reduces thermal stress and/or mechanical stress from, within, and/or around the TSVs. In some embodiments, guard ring 190-5 provides structural support, integrity, reinforcement, or combinations thereof for its TSVs.

A spacing between TSVs of a TSV cluster may be less than a spacing between TSVs having separate guard rings. For example, a spacing S1 is between TSV 170-1 and TSV 170-2 in stacked chip structure 100A (FIG. 1), a spacing S2 is between TSV 170-1 and TSV 170-2 in stacked chip structure 100B (FIG. 2A) and stacked chip structure 100C (FIG. 2B), and spacing S1 is greater than spacing S2. Spacing S1 is greater than spacing S2 to accommodate for a portion of guard ring 190-1 and a portion of guard ring 190-2 (i.e., two guard ring sides/walls) formed between TSV 170-1 and TSV 170-2 in stacked chip structure 100A. In some embodiments, spacing S1 is greater than about 3 μm. For example, spacing S1 may be about 3 μm to about 100 μm. In some embodiments, spacing S2 is greater than about 0.5 μm. For example, spacing S2 may be about 0.5 μm to about 100 μm. Configuring stacked chip structure 100B and stacked chip structure 100C with a TSV cluster thus reduces a footprint of the disclosed power delivery structure, which may increase space available for devices in device layer DL1. For example, referring to FIG. 6A and FIG. 6B, an area of stacked chip structure 100A consumed by eight TSVs (e.g., four TSVs 170-1 and four TSVs 170-2), each of which has a corresponding guard ring (e.g., guard ring 190-1 or guard ring 190-2), may be greater than an area consumed by eight TSVs of stacked chip structure 100B, which are arranged into four TSV clusters, each of which includes a respective TSV 170-1, a respective TSV 170-2, and a respective guard ring 190-4. In stacked chip structure 100B, a spacing S3 is between TSV clusters, and spacing S3 may be greater than spacing S2 to accommodate for portions of guard rings 190-4 between the TSV clusters. In some embodiments, spacing S3 is greater than about 3 μm. For example, spacing S3 may be about 3 μm to about 100 μm.

In some embodiments, all eight TSVs of stacked chip structure 100A and stacked chip structure 100B are electrically connected to a respective device layer. In such embodiments, four TSVs 170-1 may be electrically connected to device layer DL1 of chip 102, and four TSVs 170-2 may be electrically connected to device layer DL2 of chip 104. In some embodiments, some TSVs of stacked chip structure 100A and stacked chip structure 100B are dummy TSVs that are not electrically connected to a respective device layer. For example, in stacked chip structure 100A, two TSVs 170-1 may be active TSVs that are electrically connected to device layer DL1, two TSVs 170-1 may be dummy TSVs that are not electrically connected to device layer DL1, two TSVs 170-2 may be active TSVs that are electrically connected to device layer DL2, and two TSVs 170-2 may be dummy TSVs that are not electrically connected to device layer DL2. In another example, in stacked chip structure 100B, two TSV clusters may be active TSV clusters that are electrically connected to device layer DL1 and device layer DL2, and two TSV clusters may be dummy TSV clusters that are not electrically connected to device layer DL1 or device layer DL2. In some embodiments, a TSV cluster may include an active TSV and a dummy TSV, such as TSV 170-1 and TSV 170-2, respectively (or vice versa). The dummy TSVs of stacked chip structure 100A and/or stacked chip structure 100B may extend from substrate 106 to a TSV landing pad that is not electrically connected to a device layer. The dummy TSVs may enhance heat dissipation and/or structural strength.

The present disclosure contemplates various configurations and or arrangements of TSV clusters that may share a guard ring. For example, FIGS. 7A-7E illustrate various TSV clusters that may share a respective guard ring 190-4. FIG. 7A illustrates a 2×1 TSV cluster surrounded by a respective guard ring 190-4, FIG. 7B illustrates a 1×2 TSV cluster surrounded by a respective guard ring 190-4, FIG. 7C illustrates a 2×2 TSV cluster surrounded by a respective guard ring 190-4, FIG. 7D illustrates a 3×3 TSV cluster surrounded by a respective guard ring 190-4, and FIG. 7E illustrates a 2×3×2 TSV cluster surrounded by a respective guard ring 190-4. Further, FIGS. 7F-7J illustrate various TSV clusters that may share a respective guard ring 190-5. FIG. 7F illustrates a 2×1 TSV cluster surrounded by a respective guard ring 190-5, FIG. 7G illustrates a 1×2 TSV cluster surrounded by a respective guard ring 190-5, FIG. 7H illustrates a 2×2 TSV cluster surrounded by a respective guard ring 190-5, FIG. 7I illustrates a 3×3 TSV cluster surrounded by a respective guard ring 190-5, and FIG. 7J illustrates a 2×3×2 TSV cluster surrounded by a respective guard ring 190-5. In such embodiments, each TSV 170-1 and each TSV 170-2 of the TSV clusters of FIGS. 7F-7J may be surrounded by a respective portion of its respective guard ring 190-5, such as depicted. One or more TSVs of the TSV clusters of FIGS. 7A-7J may be dummy TSVs.

The disclosed power delivery structures may be incorporated into stacked chip structures having chip stacks with more than two chips, such that each chip of the chip stack has a dedicated, independent power-delivery TSV. For example, referring to FIG. 8, stacked chip structure 100D has a chip stack that includes chip 102, chip 104, and a chip 102′. Chip 102′ may include a substrate 106′, a device layer DL3, and an FMLI-3 structure, which may be similar to substrate 106 and/or substrate 108, device layer DL1 and/or device layer DL2, and FMLI-1 structure and/or FMLI-2 structure, respectively. FMLI-3 structure includes a respective V0 level, a respective M0 level, a respective V1 level, a respective M1 level, a respective V2 level, a respective M2 level, and so on to a via (Z−1) layer (V(Z−1) level), a metal (Z−1) layer (M(Z−1) level), a via Z layer (VZ level), and a metal Z layer (MZ level), where Z is an integer (e.g., from 2 to 10). Z may be the same or different than X and/or Y. Each level of FMLI-3 structure may include conductive features, such as metal lines 122′ or metal vias 124′, disposed in a portion of an insulation layer 120-1′. Metal lines 122′, metal vias 124′, and insulation layer 120-1′ may be similar to metal lines 122 and/or metal lines 126, metal vias 124 and/or metal vias 128, and insulation layer 120-1 and/or insulation layer 120-2, respectively, described herein.

Chip 102 is disposed between chip 104 and chip 102′. In the depicted embodiment, chip 102 and chip 104 are face-to-face bonded, and chip 102 and chip 102′ are back-to-face bonded (e.g., a frontside FS3 of chip 102′ (e.g., formed by FMLI-3 structure) is attached and/or bonded to backside BS1 of chip 102 (e.g., formed by substrate 106)). In some embodiments, a chip bonding structure is between chip 102 and chip 102′, and chip 102 and chip 102′ are bonded and/or attached via the chip bonding structure. In some embodiments, the chip bonding structure may include one or more bonding layers, such as one or more dielectric layers that facilitate dielectric-to-dielectric bonding. In some embodiments, the chip bonding structure is similar to the chip bonding structure between chip 102 and chip 104.

Stacked chip structure 100D includes a power delivery structure that includes TSV 170-1 electrically connected to device layer DL1 via FMLI-1 structure and TSV 170-2 electrically connected to device layer DL2 via FMLI-2 structure, such as described above. The power delivery structure further includes a TSV 170-3 electrically connected to device layer DL3 via FMLI-3 structure. For example, TSV 170-3 is connected to a respective metal line 122′ of FMLI-3 structure (e.g., of M3 level thereof), which is connected to device layer DL3 (e.g., a transistor thereof. TSV 170-3 is further electrically connected to a voltage V3, which may be generated and/or provided by a power supply source. Accordingly, TSV 170-3 may deliver and/or supply power to devices and/or device components of device layer DL3. Each chip of stacked chip structure 100D thus has a respective power-delivery TSV connected thereto, and power may be delivered directly to each chip via its respective power-delivery TSV.

In such configuration, TSV 170-1 is disposed in chip 102′ and chip 102, but not chip 104, TSV 170-2 is disposed in chip 102′, chip 102, and chip 104, and TSV 170-3 is disposed in chip 102′, but not chip 102 or chip 104. For example, TSV 170-3 is disposed in and extends through substrate 106′, device layer DL3, and into insulation layer 120-1 to M3 level of FMLI-3 structure; TSV 170-1 is disposed in and extends through substrate 106′, device layer DL3, insulation layer 120-1′, substrate 106, device layer DL1, and into insulation layer 120-1 to M3 level of FMLI-1 structure; and TSV 170-2 is disposed in and extends through substrate 106′, device layer DL3, insulation layer 120-1′, substrate 106, device layer DL1, insulation layer 120-1, the chip bonding structure, and into insulation layer 120-2 to M4 level of FMLI-2 structure. In some embodiments, TSV 170-1 may extend to a different level of FMLI-1 structure, TSV 170-2 may extend to a different level of FMLI-2 structure, TSV 170-3 may extend to a different level of FMLI-3 structure, or combinations thereof. TSV 170-3 may be similar to TSV 170-1 and/or TSV 170-2, such as described herein. For example, TSV 170-3 may include an electrically conductive core, a barrier layer, and a dielectric liner, such as described herein.

Similar to stacked chip structures 100A-100C, though the power delivery TSVs have different depths and different CDs, the power delivery TSVs have about the same aspect ratio. For example, in stacked chip structure 100D, TSV 170-3 may have a diameter D3 (and/or a width) (e.g., along the x-direction and/or the y-direction) and a height H3 (e.g., along the z-direction), diameter D3 is less than diameter D2 and diameter D1, height H3 is less than height H2 and height H1, and an aspect ratio R3 of height H3 to diameter D3 is about the same as aspect ratio R2 and aspect ratio R1 (i.e., AR1 (=H1/D1)=AR2 (=H2/D2)=AR3 (=H3/D3)). In some embodiments, diameter D3 is less than about 15 μm. For example, diameter D3 may be about 0.5 μm to about 10 μm. In some embodiments, aspect ratio R3, aspect ratio R2, and aspect ratio R1 are about 5 to about 20, such as about 10. For example, diameter D3 may be about 2 m, height H3 may be about 20 μm, diameter D1 may be about 3 μm, height H1 may be about m, diameter D2 may be about 4.5 μm, height H2 may be about 45 μm.

Each power delivery TSV has a corresponding, respective guard ring in chip 102′. For example, a guard ring 190-6 is spaced apart from and around TSV 170-3, a guard ring 190-7 is spaced apart from and around TSV 170-1, and a guard ring 190-8 is spaced apart from and around TSV 170-2. Insulation layer 120-1′ may fill spacing between guard ring 190-6 and TSV 170-3, spacing between guard ring 190-7 and TSV 170-1, and spacing between guard ring 190-8 and TSV 170-2. Guard ring 190-6, guard ring 190-7, and guard ring 190-8 may be circular rings, square rings, octagonal rings, hexagonal rings, or other suitable shaped rings. In the depicted embodiment, guard ring 190-6, guard ring 190-7, and guard ring 190-8 extend continuously around TSV 170-3, TSV 170-1, and TSV 170-2, respectively. In some embodiments, guard ring 190-6, guard ring 190-7, guard ring 190-8, or combinations thereof are discontinuous. For example, guard ring 190-6, guard ring 190-7, guard ring 190-8, or combinations thereof may be formed by discrete segments that combine to form a ring.

Guard ring 190-6, guard ring 190-7, and guard ring 190-8 may each be formed from a portion of FMLI-3 structure. In some embodiments, each of guard ring 190-6, guard ring 190-7, and guard ring 190-8 has an interconnect structure stack disposed in and extending through insulation layer 120-1′. The interconnect structure stack of guard ring 190-6 may include a g0 level, a g1 level, and a g2 level. The interconnect structure stack of guard ring 190-7 may include a g0 level, a g1 level, and so on to a guard ring g(E−1) layer (g(E−1) level), and a guard ring E layer (gE level), where E is an integer (e.g., from 2 to 10). The interconnect structure stack of guard ring 190-8 may include a g0 level, a g1 level, and so on to a guard ring g(F−1) layer (g(F−1) level), and a guard ring F layer (gF level), where F is an integer (e.g., from 2 to 10). E may be different or the same as F. Each guard ring level may be formed from one or more interconnect structures, each of which may include a respective metal line 122′ and a respective metal via 124′. In the depicted embodiment, a height of guard ring 190-6 is different than a height of guard ring 190-7 and a height of guard ring 190-8, guard ring 190-7 and guard ring 190-8 have the same height, and guard ring 190-6, guard ring 190-7, and guard ring 190-8 have uniform heights. For example, guard ring 190-6 extends from substrate 106 to M2 level on both sides of TSV 170-3, guard ring 190-7 extends from substrate 106 to MZ level on both sides of TSV 170-1 (e.g., E=Z), and guard ring 190-8 extends from substrate 106 to MZ level on both sides of TSV 170-2 (e.g., F=Z). In such example, TSV 170-3 may extend vertically beyond a top of guard ring 190-6 (e.g., to M3 level), TSV 170-1 may extend vertically beyond a top of guard ring 190-7 (e.g., to chip 102), and TSV 170-2 may extend vertically beyond a top of guard ring 190-8 (e.g., to chip 104). In some embodiments, guard ring 190-6 is not connected to TSV 170-3, guard ring 190-7 is not connected to TSV 170-1, and guard ring 190-8 is not connected to TSV 170-2. The present disclosure contemplates different guard ring heights.

In some embodiments, guard ring 190-6, guard ring 190-7, guard ring 190-8, or combinations thereof are electrically connected to a voltage. In some embodiments guard ring 190-6, guard ring 190-7, guard ring 190-8, or combinations thereof are electrically connected to an electrical ground. In some embodiments, guard ring 190-6, guard ring 190-7, and guard ring 190-8 are configured to electrically insulate TSV 170-3, TSV 170-1, and TSV 170-2, respectively, from device regions of chip 102′. In some embodiments, guard ring 190-6, guard ring 190-7, guard ring 190-8, or combinations thereof absorb and/or reduce thermal stress and/or mechanical stress from, within, and/or around the TSVs. In some embodiments, guard ring 190-6, guard ring 190-7, guard ring 190-8, or combinations thereof provide structural support, integrity, reinforcement, or combinations thereof for the TSVs.

In the various embodiments, insulation layer 120-1 and insulation layer 120-2 each include a dielectric material, such as silicon oxide, tetraethylorthosilicate (TEOS) oxide, phosphosilicate glass (PSG), boron-doped silicate glass (BSG), boron-doped PSG (BPSG), low-k dielectric material (having, for example, a dielectric constant that is less than a dielectric constant of silicon oxide (e.g., k<3.9)), other suitable dielectric material, or combinations thereof. Exemplary low-k dielectric materials include fluorosilicate glass (FSG), carbon-doped oxide, xerogel, aerogel, amorphous fluorinated carbon, parylene, BCB, polyimide, other low-k dielectric material, or combinations thereof. In some embodiments, insulation layer 120-1 and/or insulation layer 120-2 include a low-k dielectric material, such as carbon-doped oxide, or an extreme low-k dielectric material (e.g., k<2.5), such as porous carbon-doped oxide. Dielectric layer 116, dielectric layer 130, and dielectric layers 134-138, which may form a portion of insulation layer 120-1, and dielectric layer 124, dielectric layer 140, and dielectric layers 146-158, which may form a portion of insulation layer 120-2, may include any suitable dielectric material and/or have a multilayer structure (e.g., ILD and CESL), such as described herein.

In some embodiments, insulation layer 120-1 and/or insulation layer 120-2 have a multilayer structure. For example, insulation layer 120-1 and/or insulation layer 120-2 may each include at least one ILD layer, at least one CESL disposed between respective ILD layers, and at least one CESL disposed between a respective ILD layer and device substrates (e.g., substrate 106 and/or substrate 108). A material of the CESL may be different than a material of the ILD layer. For example, where the ILD layer includes a low-k dielectric material that includes silicon and oxygen, the CESL may include silicon and nitrogen (e.g., silicon nitride, silicon oxynitride, silicon carbonitride, or combinations thereof) or other suitable dielectric material (e.g., metal nitride). The ILD layer may have a multilayer structure having multiple dielectric materials. The CESL may have a multilayer structure having multiple dielectric materials.

In some embodiments, each level of FMLI-1 structure (e.g., 2^{nd} level including M2 level and V2 level) includes a respective ILD layer and/or a respective CESL of insulation layer 120-1, and respective metal lines 122 and metal vias 124 are in the respective ILD layer and/or the respective CESL. In some embodiments, each level of FMLI-2 structure includes a respective ILD layer and/or a respective CESL of insulation layer 120-2, and respective metal lines 126 and metal vias 128 are in the respective ILD layer and/or the respective CESL. In some embodiments, each of M0 level to MX level of FMLI-1 structure may include a respective ILD layer and/or a respective CESL, where respective metal lines 122 are in the respective ILD layer and/or the respective CESL. In some embodiments, each of M0 level to MY level of FMLI-2 structure may include a respective ILD layer and/or a respective CESL, where respective metal lines 126 are in the respective ILD layer and/or the respective CESL In some embodiments, each of V0 level to VX level of FMLI-1 structure may include a respective ILD layer and/or a respective CESL, where respective metal vias 124 are in the respective ILD layer and/or the respective CESL. In some embodiments, each of V0 level to VY level of FMLI-2 structure may include a respective ILD layer and/or a respective CESL, where respective metal vias 128 are in the respective ILD layer and/or the respective CESL.

Further, in the various embodiments described herein, metal lines 122, metal vias 124, metal lines 126, metal vias 128, source/drain contacts (e.g., source/drain contact 142), source/drain vias (e.g., source/drain via 144), and gate contacts (e.g., gate contact 132), include an electrically conductive material, including for example, aluminum, copper, titanium, tantalum, tungsten, ruthenium, cobalt, iridium, palladium, platinum, nickel, tin, gold, silver, other suitable metals, alloys thereof, silicides thereof, or combinations thereof. In some embodiments, metal lines 122, metal vias 124, metal lines 126, metal vias 128, source/drain contacts, source/drain vias, gate contacts, or combinations thereof include a bulk metal layer (also referred to as a metal fill layer, a conductive plug, a metal plug, etc.). In some embodiments, metal lines 122, metal vias 124, metal lines 126, metal vias 128, source/drain contacts, source/drain vias, gate contacts, or combinations thereof include a barrier layer, an adhesion layer, other suitable layer, or combinations thereof disposed between the bulk metal layer and a respective insulation layer. The barrier layer may include titanium, titanium alloy (e.g., TiN), tantalum, tantalum alloy (e.g., TaN), other suitable barrier material (e.g., a material that may prevent diffusion of metal constituents from the bulk metal layer into a surrounding dielectric), or combinations thereof. In some embodiments, metal lines 122, metal vias 124, metal lines 126, metal vias 128, source/drain contacts, source/drain vias, gate contacts, or combinations thereof include different metal materials. For example, lower metal lines 122 and/or metal vias 124, which are closer to device layer DL1, may include tungsten, ruthenium, cobalt, or combinations thereof, while higher metal lines 122 and/or metal vias 124, which are further away from device layer DL1, may include copper. In another example, lower metal lines 126 and/or metal vias 128, which are closer to device layer DL2, may include tungsten, ruthenium, cobalt, or combinations thereof, while higher metal lines 126 and/or metal vias 128, which are further away from device layer DL2, may include copper. In some embodiments, metal lines 122, metal vias 124, metal lines 126, metal vias 128, source/drain contacts, source/drain vias, gate contacts, or combinations thereof include the same metal materials.

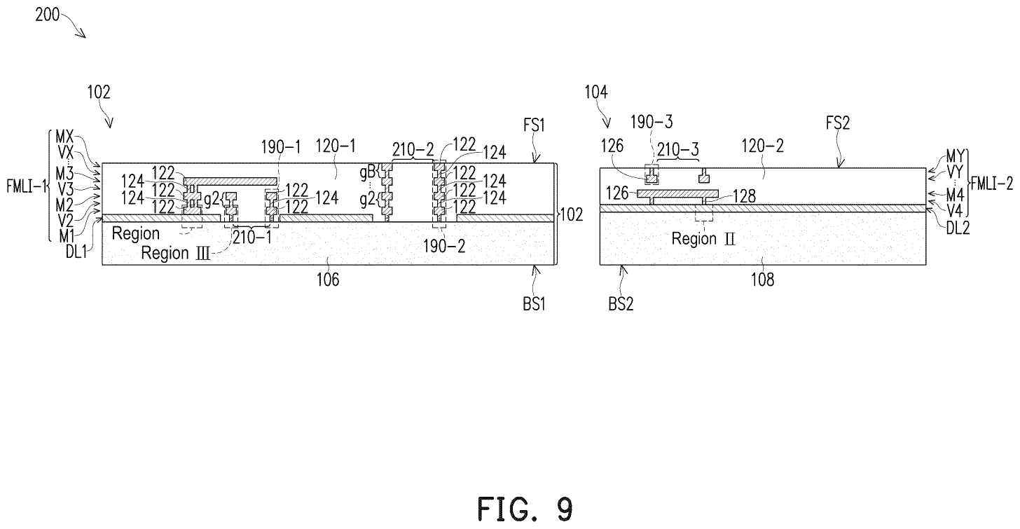

Referring to FIGS. 9-17, FIGS. 9-17 are cross-sectional views of a stacked chip structure 200, in portion or entirety, at various fabrication stages of forming a power delivery structure, such as the power delivery structure of stacked chip structure 100A of FIG. 1, according to various aspects of the present disclosure. FIGS. 9-17 have been simplified for the sake of clarity to better understand the inventive concepts of the present disclosure. Additional features can be added in stacked chip structure 200, and some of the features described below can be replaced, modified, or eliminated in other embodiments of stacked chip structure 200.

Referring to FIG. 9, after stacked chip structure 200 undergoes FEOL processing (e.g., to form device layer DL1 and device layer DL2 of chip 102 and chip 104, respectively), stacked chip structure 200 may undergo MEOL processing and BEOL processing to form FMLI-1 structure (e.g., M0 level to MX level and V0 level to VX level) over device layer DL1. FMLI-1 structure may be connected to devices, such as transistors (e.g., transistor T1 and/or transistor T2), of device layer DL1. Interconnect structure stacks of guard ring 190-1 (e.g., g0 level to g2 level) and guard ring 190-2 (e.g., g0 level to gB level) may be formed over device layer DL1 while forming FMLI-1 structure. Interconnect structure stacks of guard ring 190-1 and guard ring 190-2 may be connected to device layer DL1, such as to doped regions formed in substrate 106. Guard ring 190-1 may be a metal ring (FIGS. 4A-4C) having an inner dimension that defines a dielectric region 210-1 of insulation layer 120-1, and guard ring 190-2 may be a metal ring having an inner dimension that defines a dielectric region 210-2 of insulation layer 120-1. As described herein, TSV 170-1 and TSV 170-2 will be formed in and extend through dielectric region 210-1 and dielectric region 210-2, respectively. A portion of FMLI-1 structure (e.g., a respective metal line 122 of M3 level) overlaps guard ring 190-1 and will provide a TSV landing pad of chip 102. In some embodiments, guard ring 190-1 and guard ring 190-2 have uniform heights. For example, both sides of guard ring 190-1 may extend from device layer DL1 to M2 level, and both sides of guard ring 190-2 may extend from device layer DL2 to MX level.

In some embodiments, forming a given level of FMLI-1 structure (e.g., metal vias 124 of V2 level and metal lines 122 of M2 level) and interconnect structures of guard ring 190-1 and guard ring 190-2 at the given level (e.g., metal vias 124 and metal lines 122 of g2 level) includes depositing a portion of insulation layer 120-1, such as depositing an ILD layer of insulation layer 120-1 over a frontside of substrate 106. In some embodiments, depositing the portion of insulation layer 120-1 includes depositing a CESL before depositing the ILD layer, such that the ILD layer is deposited over the CESL. The portion of insulation layer 120-1 (e.g., the ILD layer and/or the CESL) are formed by chemical vapor deposition (CVD), atomic layer deposition (ALD), other suitable deposition method, or combinations thereof. A planarization process may be performed after depositing the portion of insulation layer 120-1.

In some embodiments, metal lines 122 and metal vias 124 of a given level of FMLI-1 structure and interconnect structures of guard ring 190-1 and guard ring 190-2 at the given level are formed by a dual damascene process, which may involve depositing conductive material for via/metal line pairs at the same time. In such embodiments, metal vias 124 and metal lines 122 may share a barrier layer and a conductive plug, instead of each having a respective and distinct barrier layer and conductive plug (e.g., where a barrier layer of a respective metal line 122 separates a conductive plug of the respective metal line 122 from a conductive plug of its corresponding, respective metal via 124). In some embodiments, the dual damascene process includes performing a patterning process to form interconnect openings that extend through a portion of insulation layer 120-1 to expose underlying conductive features. The patterning process may include a first lithography step and a first etch step to form trench openings of the interconnect openings (which correspond with metal lines 122) in insulation layer 120-1 and a second lithography step and a second etch step to form via openings of the interconnect openings (which correspond with metal vias 124) in insulation layer 120-1. The first lithography/etch step and the second lithography/etch step may be performed in any order (e.g., trench first via last or via first trench last). The first etch step and the second etch step are configured to selectively remove insulation layer 120-1 with respect to a patterned mask layer. The first etch step and the second etch step may be a dry etch, a wet etch, other suitable etch, or combinations thereof.

After performing the patterning process, the dual damascene process may include performing a first deposition process to form a barrier material over insulation layer 120-1 that partially fills the interconnect openings and performing a second deposition process to form a bulk conductive material over the barrier material, where the bulk conductive material fills remainders of the interconnect openings. In such embodiments, the barrier material and the bulk conductive material may be disposed in the interconnect openings and over a top surface of insulation layer 120-1. The first deposition process and the second deposition process may be CVD, PVD, ALD, other suitable deposition method, or combinations thereof. A CMP process and/or other planarization process may be performed to remove excess bulk conductive material and barrier material from over a top surface of the portion of insulation layer 120-1, resulting in the patterned via layer (e.g., metal vias 124) and the patterned metal layer (e.g., metal lines 122) of the given level of FMLI-1 structure and corresponding interconnect structures of guard ring 190-1 and guard ring 190-2. The CMP process planarizes top surfaces of insulation layer 120-1 and metal lines 122. The barrier material and the bulk conductive material may fill the trench openings and the via openings of the interconnect openings without interruption, such that metal lines 122 and metal vias 124 share a barrier layer and a conductive plug.

In some embodiments, for a given level of FMLI-1 structure, metal lines 122 and metal vias 124 of interconnect structures of guard ring 190-1 and guard ring 190-2 at the given level are formed simultaneously with the metal lines 122 and metal vias 124, respectively, of the given level of FMLI-1 structure. In some embodiments, for a given level of FMLI-1 structure, metal lines 122 and metal vias 124 of interconnect structures of guard ring 190-1 and guard ring 190-2 at the given level are formed at least partially simultaneously with metal lines 122 and metal vias 124, respectively, of the given level of FMLI-1 structure. In some embodiments, for a given level of FMLI-1 structure, metal lines 122 and metal vias 124 of interconnect structures of guard ring 190-1 and guard ring 190-2 at the given level are formed by different processes than metal lines 122 and metal vias 124, respectively, of the given level of FMLI-1 structure. In some embodiments, for a given level of FMLI-1 structure, metal lines 122 and metal vias 124 of interconnect structures of guard ring 190-1 and guard ring 190-2 at the given level and metal lines 122 and/or metal vias 124, respectively, of the given level of FMLI-1 structure are formed by the same single damascene process. In some embodiments, for a given level of FMLI-1 structure, metal lines 122 and metal vias 124 of interconnect structures of guard ring 190-1 and guard ring 190-2 at the given level and metal lines 122 and/or metal vias 124, respectively, of the given level of FMLI-1 structure are formed by different single damascene processes. In some embodiments, for a given level of FMLI-1 structure, metal lines 122 and metal vias 124 of interconnect structures of guard ring 190-1 and guard ring 190-2 at the given level and metal lines 122 and/or metal vias 124, respectively, of the given level of FMLI-1 structure are formed by the same dual damascene process. In some embodiments, for a given level of FMLI-1 structure, metal lines 122 and metal vias 124 of interconnect structures of guard ring 190-1 and guard ring 190-2 at the given level and metal lines 122 and/or metal vias 124, respectively, of the given level of FMLI-1 structure are formed by different dual damascene processes. In some embodiments, guard ring 190-1 and guard ring 190-2 are formed simultaneously. In some embodiments, guard ring 190-1 and guard ring 190-2 are formed separately.

MEOL processing and BEOL processing of stacked chip structure 200 may also include forming FMLI-2 structure (e.g., M0 level to MY level and V0 level to VY level) over device layer DL2. FMLI-2 structure may be connected to devices, such as transistors (e.g., transistor T3 and/or transistor T4), of device layer DL2. Interconnect structure stacks of guard ring 190-3 (e.g., gC level and lower) may be formed over device layer DL2 while forming FMLI-2 structure. Guard ring 190-3 may be a metal ring having an inner dimension that defines a dielectric region 210-3 of insulation layer 120-2. As described further herein, TSV 170-2 will also be formed in and extend through dielectric region 210-3, and guard ring 190-3 overlaps a portion of FMLI-2 structure (e.g., a respective metal line 126 of M4 level or above) that will provide a TSV landing pad of chip 104. In some embodiments, such as depicted, guard ring 190-3 may have a uniform height. A given level of FMLI-2 structure (e.g., metal vias 128 of VY level and metal lines 126 of MY level) and interconnect structures of guard ring 190-3 at the given level (e.g., metal vias 128 and metal lines 126 of gC level) may be formed as described above with reference to forming a given level of FMLI-1 structure and interconnect structures of guard ring 190-1 and guard ring 190-2 at the given level. For example, insulation layer 120-2, metal lines 126, and metal vias 128 may be formed in a manner similar to insulation layer 120-1, metal lines 122, and metal vias 124, respectively, such as described above.

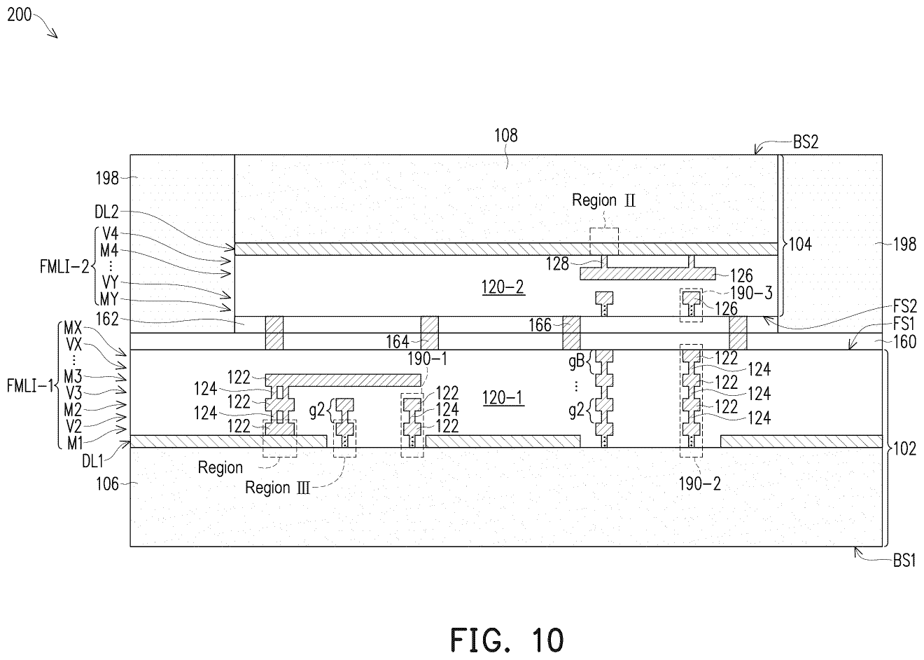

Referring to FIG. 10, chip 104 is face-to-face bonded to chip 102 to form a chip stack. In some embodiments, FMLI-2 structure is hybrid bonded to FMLI-1 structure. For example, hybrid bonding may include forming bonding layer 160 having bonding pads 164 disposed therein over frontside FS1 of chip 102 (e.g., formed by MX layer of FMLI-1 structure); forming bonding layer 162 having bonding pads 166 disposed therein over frontside FS2 of chip 104 (e.g., formed by MY layer of FMLI-2 structure); flipping over chip 104 so that its frontside FS2 faces frontside FS1 of chip 102; aligning chip 104 with chip 102 (e.g., aligning bonding pads 166 and bonding pads 164); and pressing chip 104 and chip 102 together to effectuate bonding of bonding pads 166 and bonding pads 164 (e.g., metal-to-metal bonding) and/or of bonding layer 162 and bonding layer 160 (e.g., non-metal-to-non-metal bonding). In some embodiments, the bonding includes performing an anneal process (e.g., heat application) and/or other suitable process to effectuate bonding of bonding pads 166 and bonding pads 164 and/or bonding of bonding layer 162 and bonding layer 160. In some embodiments, the bonding includes aligning a TSV landing pad of chip 104 (e.g., provided by a respective metal line 126 of M4 level in the depicted embodiment) with guard ring 190-2 of chip 102. For example, TSV landing pad of chip 104 may be center aligned with guard ring 190-2 and/or dielectric region 210-3. In some embodiments, the bonding includes aligning guard ring 190-3 with guard ring 190-2. For example, guard ring 190-3 may be center aligned with guard ring 190-2.

After the bonding, encapsulant 198 and/or molding may be formed around chip 104 and over chip 102. Encapsulant 198 may encase chip 104. Encapsulant 198 may cover exposed portions of bonding layer 160 (i.e., those portions not covered by chip 104) and sidewalls of chip 104. Encapsulant 198 may fill space between sidewalls of chip 104 and sidewalls of chip 102. In some embodiments, forming encapsulant 198 includes depositing an encapsulant material, such as a polymer material and/or a dielectric material, and performing a planarization process, which may remove encapsulant material covering backside BS2 of chip 104.

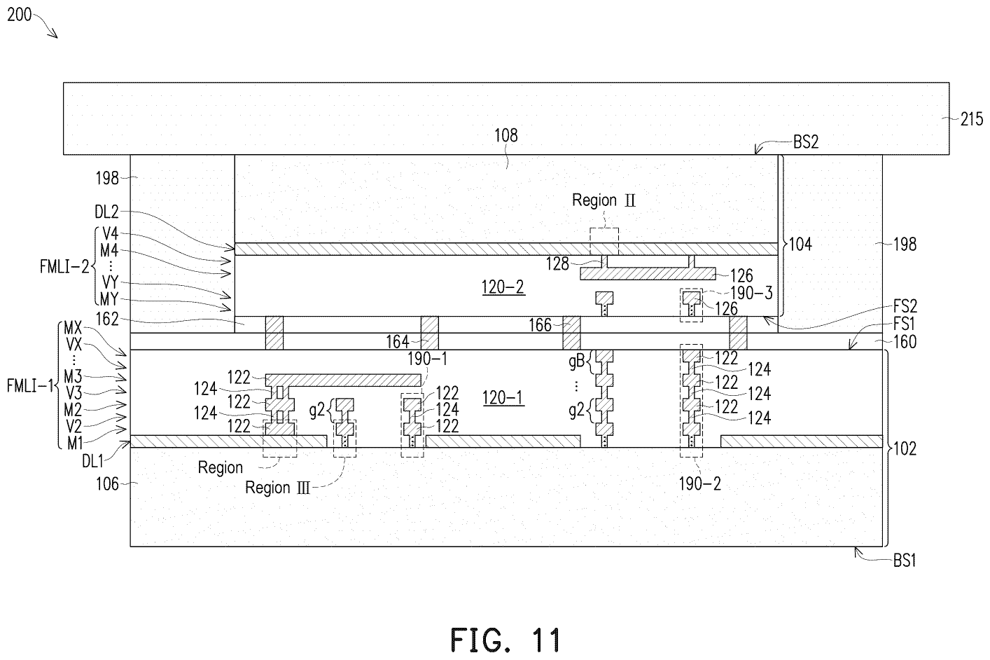

Referring to FIG. 11, in some embodiments, a carrier substrate 215 is attached to a frontside of stacked chip structure 200, which allows stacked chip structure 200 to be flipped over and accessible for backside processing. Carrier substrate 215 may be attached by direct bonding, hybrid bonding, adhesive, other bonding and/or attachment technique/process, or combinations thereof. In some embodiments, carrier substrate 215 is attached to backside BS2 of chip 104 and encapsulant 198. The bonding process may include alignment, annealing, other processes, or combinations thereof. In some embodiments, carrier substrate 215 includes silicon, soda-lime glass, fused silica, fused quartz, calcium fluoride, other suitable carrier substrate material, or combinations thereof. In some embodiments, carrier substrate 215 is configured to provide sufficient rigidity and/or mechanical support. In some embodiments, carrier substrate 215 is attached to substrate 108 and/or encapsulant 198 by a bonding layer. The bonding layer may be an oxide layer and/or another suitable material layer that facilitates bonding of carrier substrate 215 with substrate 108 and/or encapsulant 198. In some embodiments, carrier substrate 215 is attached to substrate 108 and/or encapsulant 198 by a suitable adhesive.

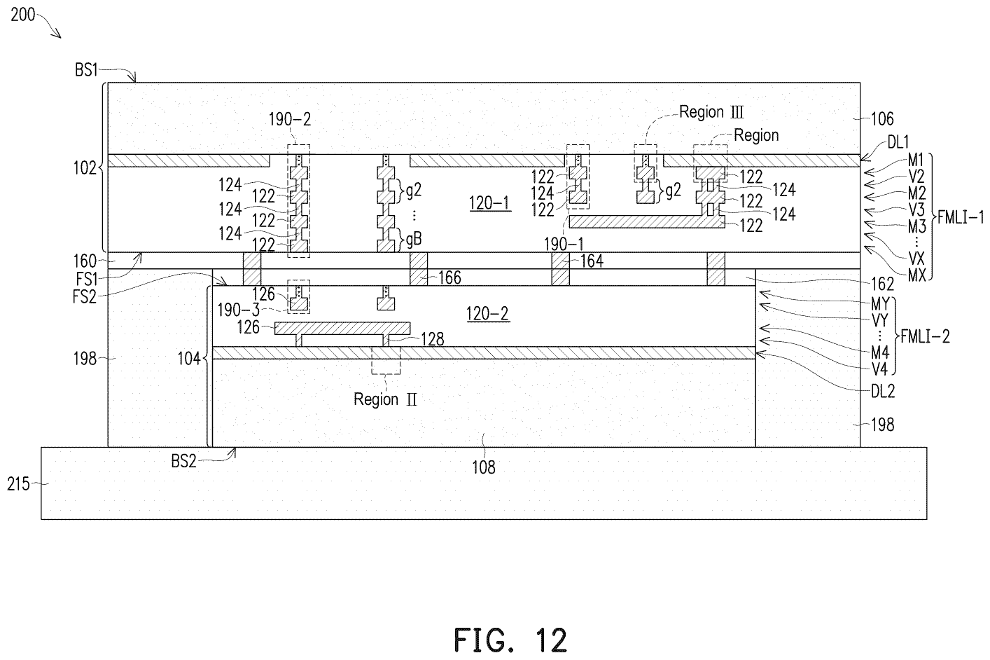

Referring to FIG. 12, stacked chip structure 200 is flipped over and a thinning process is applied to backside BS1 of substrate 106 of chip 102. The thinning process reduces a thickness of substrate 106 (e.g., along the z-direction). The thinning process is a grinding process, a planarization process (e.g., CMP), an etching process, other suitable process, or combinations thereof. In some embodiments, the thinning process is a multistep process, such as a mechanical grinding process to remove a sufficient amount of substrate 106 and then a chemical thinning process (e.g., using an etching chemical) to further thin substrate 106.

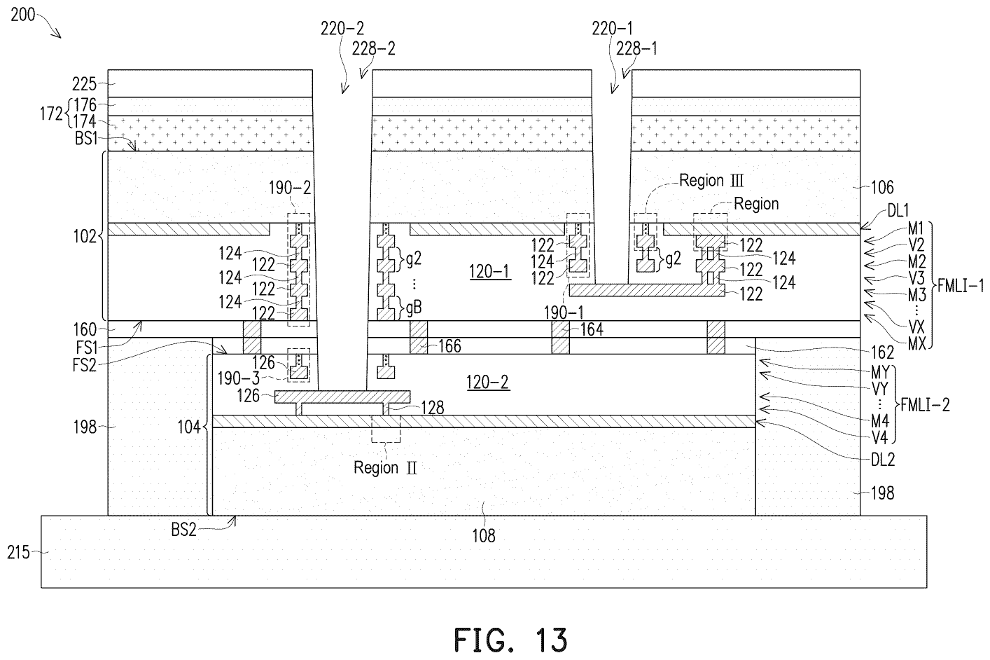

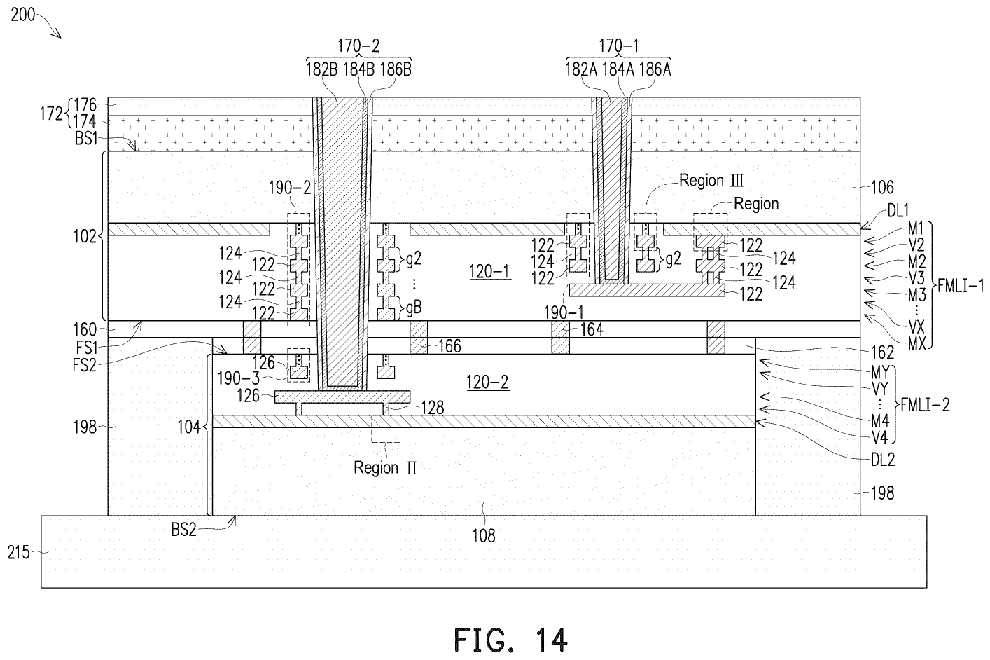

Referring to FIG. 13 and FIG. 14, processing of stacked chip structure 200 may proceed with forming TSVs to each chip of the chip stack, such as TSV 170-1 and TSV 170-2 to chip 102 chip 104, respectively. TSV 170-1 and TSV 170-2 are formed simultaneously by any suitable process. Referring to FIG. 13, forming the TSVs may include forming a TSV trench 220-1 that exposes a TSV landing pad of chip 102 (e.g., provided by a respective metal line 122 of M3 level) and a TSV trench 220-2 that exposes a TSV landing pad of chip 104 (e.g., provided by a respective metal line 126 of M4 level). TSV landing pad of chip 102 is electrically connected to one or more devices and/or device components of device layer DL1 via electrically conductive portions of FMLI-1 structure (e.g., a routing path formed by a combination of metal lines 122 and metal vias 124), and TSV landing pad of chip 104 is electrically connected to one or more devices and/or device components of device layer DL2 via electrically conductive portions of FMLI-2 structure (e.g., a routing path formed by a combination of metal lines 126 and metal vias 128). TSV trench 220-1 extends through substrate 106, device layer DL1, and into insulation layer 120-1. TSV trench 220-2 extends through substrate 106, device layer DL1, insulation layer 120-1, the chip bonding structure (e.g., bonding layer 160 and bonding layer 162 thereof), and into insulation layer 120-2. TSV trench 220-1 is formed in dielectric region 210-1 of insulation layer 120-1, such that guard ring 190-1 is around TSV trench 220-1, and TSV trench 220-2 is formed in dielectric region 210-2 of insulation layer 120-1 and dielectric region 210-3 of insulation layer 120-2, such that guard ring 190-2 and guard ring 190-3 are around TSV trench 220-2. In some embodiments, insulation layer 172 is formed over backside BS1 of chip 102 before forming the TSV trenches. In such embodiments, TSV trench 220-1 and TSV trench 220-2 may also extend through dielectric layer 176 and dielectric layer 174.

In some embodiments, forming the TSV trenches includes forming a patterned mask layer 225 having openings (e.g., an opening 228-1 and an opening 228-2) therein that overlap dielectric regions defined by guard rings of chip 102 and/or chip 104. For example, opening 228-1 overlaps dielectric region 210-1 of insulation layer 120-1, which is defined by guard ring 190-1 of chip 102, and opening 228-2 overlaps dielectric region 210-2 of insulation layer 120-1, which is defined by guard ring 190-2, and dielectric region 210-3, which is defined by guard ring 190-3. Patterned mask layer 225 may be formed by a lithography process, which may include resist coating (e.g., spin-on coating), soft baking, mask aligning, exposure, post-exposure baking, developing the resist, rinsing, drying (e.g., hard baking), other suitable process, or combinations thereof. In some embodiments, patterned mask layer 225 is a patterned hard mask layer. In some embodiments, patterned mask layer 225 is a patterned resist layer.

In some embodiments, forming the TSV trenches includes etching chip 102 and chip 104 using patterned mask layer 225 as an etch mask. For example, portions of insulation layer 172, substrate 106, device layer DL1, and insulation layer 120-1 overlapped and exposed by opening 228-1 are removed by an etching process to form TSV trench 220-1, and portions of insulation layer 172, substrate 106, device layer DL1, insulation layer 120-1, the chip bonding structure, and insulation layer 120-2 overlapped and exposed by opening 228-2 are removed by the etching process to form TSV trench 220-2. The etching process may selectively remove insulation layer 120-1 and insulation layer 120-2 with respect to metal lines 122 and metal lines 126, respectively. For example, the etching process etches insulation layer 120-1 with no (or negligible) etching of metal lines 122, and the etching process etches insulation layer 120-2 with no (or negligible) etching of metal lines 126, such that the etching my stop upon reaching the TSV landing pads. TSV trench 220-1 and TSV trench 220-2 may thus be simultaneously etched into stacked chip structure 200 despite TSV trench 220-1 and TSV trench 220-2 having different depths and different CDs (e.g., different diameters/widths). In some embodiments, an etchant of the etching process may etch dielectric material (e.g., insulation layer 120-1 and insulation layer 120-2) at a higher rate than metal material (e.g., metal lines 122 and/or metal lines 126).

The TSV etching process may be a dry etch, a wet etch, other etch, or combinations thereof. In some embodiments, the TSV etching process is an isotropic dry etch. In some embodiments, a Bosch process is implemented to extend the TSV trenches through substrate 106, device layer DL1, insulation layer 120-1, the chip bonding structure, insulation layer 120-2, or combinations thereof. A Bosch process generally refers to a high-aspect ratio plasma etching that involves alternating etch phases and deposition phases, where a cycle includes an etch phase and a deposition phase and the cycle is repeated until a TSV trench has a desired depth. In some embodiments, the TSV etching process is a multistep process, which may implement different etchants and/or different etch parameters to separately etch insulation layer 172, substrate 106, device layer DL1, insulation layer 120-1, the chip bonding structure, insulation layer 120-2, or combinations thereof. The TSV etching process may remove patterned mask layer 225, in portion or entirety, from over insulation layer 172. In some embodiments, patterned mask layer 225 is removed by another etching process and/or a resist stripping process.

Referring to FIG. 14, forming the TSVs may further include filling the TSV trenches with an electrically conductive material. In some embodiments, filling TSV trench 220-1 and TSV trench 220-2 includes depositing a dielectric material (e.g., SiN, SiCN, and/or oxide) over the backside of stacked chip structure 200 that partially fills TSV trench 220-1 and TSV trench 220-2, depositing a barrier material (e.g., Ti, TiN, and/or TaN) over the dielectric material that partially fills TSV trench 220-1 and TSV trench 220-2, depositing a bulk electrically conductive material (e.g., Cu) over the barrier material that fills a remainder of TSV trench 220-1 and TSV trench 220-2, and performing a planarization process (e.g., CMP) that removes excess dielectric material, barrier material, and bulk electrically conductive material from over insulation layer 172. Insulation layer 172 (e.g., dielectric layer 176 thereof) may function as a planarization stop layer, and the planarization process may be performed until reaching insulation layer 172. In some embodiments, the planarization process removes patterned mask layer 225.

A remainder of the dielectric material forms dielectric liners (e.g., dielectric liner 186A and dielectric liner 186B), a remainder of barrier material forms barrier layers (e.g., barrier layer 184A and barrier layer 184B), and a remainder of the bulk electrically conductive material forms electrically conductive cores (e.g., electrically conductive core 182A and electrically conductive core 182B) of the TSVs. The various layers of TSV 170-1 and TSV 170-2 may thus be deposited simultaneously. The dielectric material is formed by CVD (e.g., PECVD and/or LPCVD), thermal oxidation, chemical oxidation, other suitable deposition process, or combinations thereof. The barrier material is formed by PVD, CVD, ALD, other suitable deposition process, or combinations thereof. The electrically conductive bulk material is formed by electrochemical plating (ECP), electroplating, electroless plating, PVD, CVD, other suitable deposition process, or combinations thereof. In some embodiments, the dielectric material and the barrier material are conformally deposited over stacked chip structure 200, such that the dielectric material and the barrier material have substantially uniform thicknesses. In some embodiments, the electrically conductive bulk material is blanket deposited.

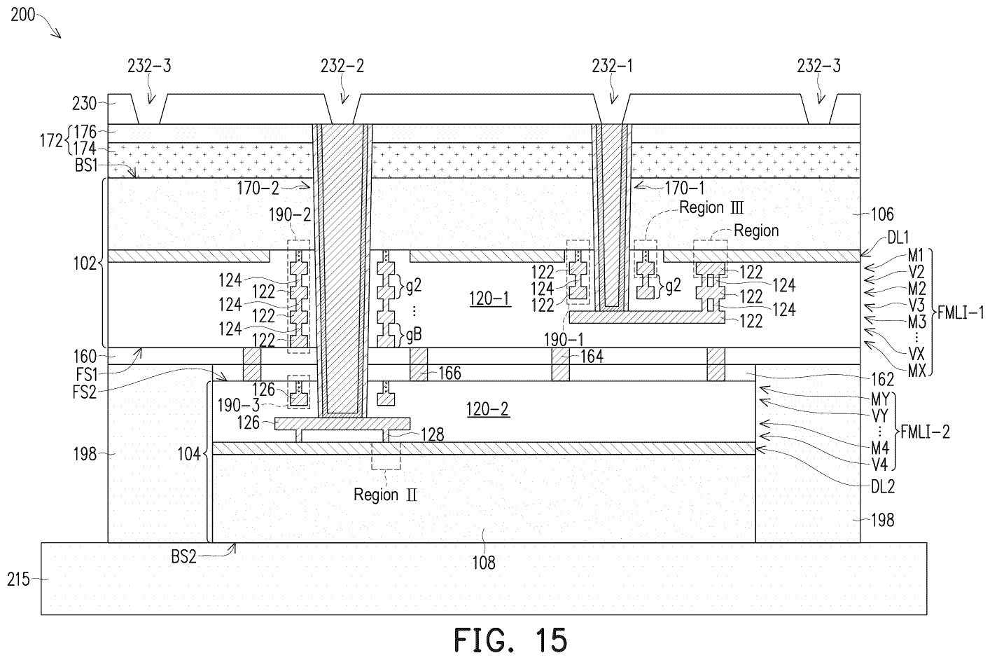

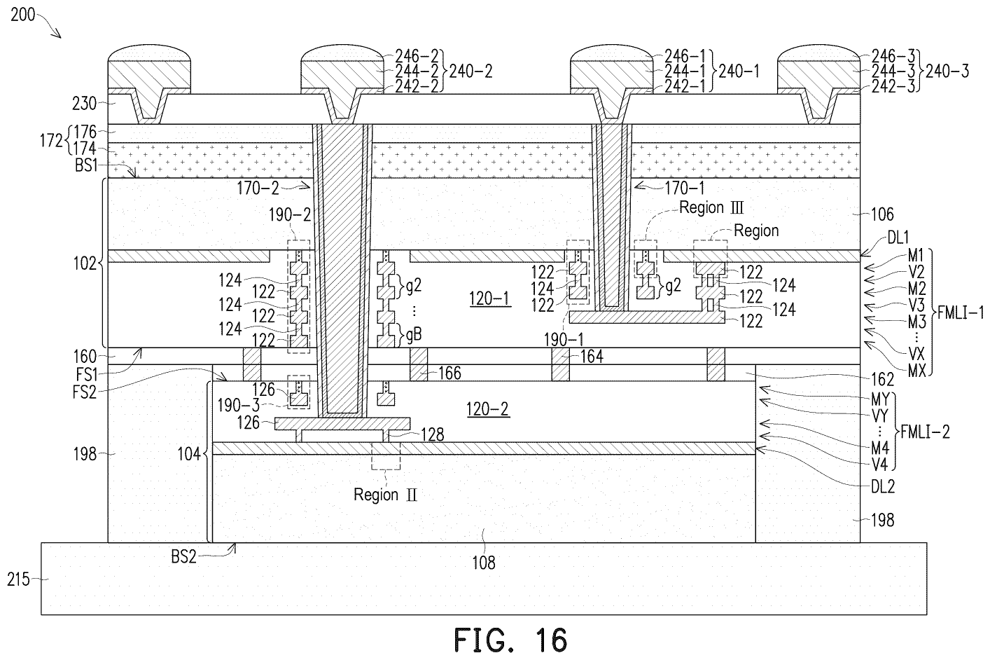

Referring to FIG. 15 and FIG. 16, stacked chip structure 200 may be processed to form a bump structure over a backside BS1 of chip 102. The bump structure may electrically connect chip 102 and/or chip 104 to a power supply, such as described herein. Referring to FIG. 15, forming the bump structure may include forming a patterned passivation layer 230 over backside BS1 of chip 102. Patterned passivation layer 230 may be formed over insulation layer 172, such that insulation layer 172 is between patterned passivation layer 230 and backside BS1 of chip 102. Patterned passivation layer 230 has openings therein that expose TSVs, such as an opening 232-1 that exposes TSV 170-1 and an opening 232-2 that exposes TSV 170-2. In some embodiments, patterned passivation layer 230 has openings 232-3 therein that expose insulation layer 172. Patterned passivation layer 230 includes an electrically insulating material, such as polyimide, undoped silicate glass, BCB, polybenzoxazole, silicon oxynitride, silicon nitride, silicon oxide, epoxy, other suitable insulating material, or combinations thereof. For example, patterned passivation layer 230 is a patterned polyimide layer. In some embodiments, patterned passivation layer 230 has a multilayer structure having multiple dielectric materials. For example, patterned passivation layer 230 may include a SiN layer and a USG layer.

Patterned passivation layer 230 may be formed by depositing the electrically insulating material over the backside of stacked chip structure 200 and performing a patterning process on the electrically insulating material to form the openings therein. The patterning process may include a lithography process and an etching process. The lithography process may form a patterned resist layer over the electrically insulating material, and the patterned resist layer may have openings therein that overlap TSV 170-1 and TSV 170-2. The lithography process may include resist coating, soft baking, mask aligning, exposure, post-exposure baking, developing the resist, rinsing, drying, other suitable process, or combinations thereof. The etching process may then use the patterned resist layer as an etch mask. For example, the etching process may remove portions of the electrically insulating material exposed by the openings of the patterned resist layer. The etching process may be performed until reaching and exposing the TSVs and/or insulation layer 172. The etching process may be a dry etch, a wet etch, other suitable etch, or combinations thereof. In some embodiments, the etching process removes the patterned resist layer, in portion or entirety, from over the electrically insulating material. In some embodiments, the patterned resist layer is removed by a resist stripping process or other etching process.

Referring to FIG. 16, forming the bump structure may include forming a connector 240-1 in opening 232-1 and over TSV 170-1, a connector 240-2 in opening 232-2 and over TSV 170-2, and connectors 240-3 in openings 232-3 and over insulation layer 172. Chip 102 and chip 104 may be electrically connected to external circuitry, another chip, a package substrate, a printed circuit board (PCB), an interposer, other package component, or combinations thereof, by connector 240-1 and connector 240-2, respectively. For example, TSV 170-1 may be electrically connected to a power supply source by connector 240-1, where the power supply source may be configured to provide voltage v1 to chip 102, and TSV 170-2 may be electrically connected to a power supply source by connector 240-2, where the power supply source may be configured to provide voltage v2 to chip 104. Each connector may include a respective under-bump metallization (UBM) layer, a respective pillar, and a respective solder bump/cap. For example, connector 240-1 may include a UBM layer 242-1, a pillar 244-1, and a bump 246-1; connector 240-2 may include a UBM layer 242-2, a pillar 244-2, and a bump 246-2; and connectors 240-3 may include a UBM layer 242-3, a pillar 244-3, and a bump 246-3. In some embodiments, connector 240-1, connector 240-2, connectors 240-3, or combinations thereof may be formed as controlled-collapse chip connection bumps (C4 bumps), ball grid array (BGA) bumps, land grid array (LGA) bumps, pin grid array (PGA) bumps, microbumps, or the like.

Connector 240-1, connector 240-2, and connectors 240-3 may be formed by a bumping process. One or more patterning processes (e.g., lithography processes and/or etching processes) may be performed to pattern one or more of the layers deposited during the bumping process. The bumping process may include forming UBM layers in the openings of patterned passivation layer 230. For example, UBM layer 242-1 may be formed in opening 232-1 over TSV 170-1, UBM layer 242-2 may be formed in opening 232-2 over TSV 170-2, and UBM layers 242-3 may be formed in openings 232-3 over insulation layer 172. In some embodiments, the UBM layers provide low resistance electrical connections between pillar/bumps and TSVs. In some embodiments, the UBM layers hermetically seal and prevent diffusion of metals from the pillars/bumps into stacked chip structure 200. In some embodiments, the UBM layers have a multilayer structure, which may include an adhesion layer, a diffusion barrier layer, a seed layer, an oxidation barrier layer, other suitable layer, or combinations thereof. In some embodiments, the adhesion layer includes titanium, chromium, aluminum, other metal, alloys thereof, or combinations thereof. In some embodiments, the diffusion barrier layer includes titanium, tantalum, other metal, alloys thereof, or combinations thereof. In some embodiments, the seed layer includes copper, other metal, alloys thereof, or combinations thereof. In some embodiments, the oxidation barrier layer includes gold, other metal, alloys thereof, or combinations thereof. The UBM layers may be formed by depositing one or more UBM materials over patterned passivation layer 230 (e.g., by CVD, PVD, electroplating, sputtering, evaporation, other method, or combinations thereof), where the one or more UBM materials partially fill the openings therein, and patterning the one or more UBM materials. In some embodiments, the UBM layers may be omitted from the bump structure.

The bumping process may include forming the pillars in the openings of patterned passivation layer 230. For example, pillar 244-1 may be formed in opening 232-1 over UBM layer 242-1, pillar 244-2 may be formed in opening 232-2 over UBM layer 242-2, and pillars 244-3 may be formed in openings 232-3 over UBM layers 242-3. In some embodiments, the pillars include copper or alloys thereof, and thus, the pillars may be referred to as copper pillars. In some embodiments, a seed layer, such as a copper seed layer, may be formed before forming the pillars, which may be formed by an electroplating process and/or other process.

The bumping process may include forming the solder bumps/caps over the pillars. For example, bump 246-1 may be formed over pillar 244-1, bump 246-2 may be formed over pillar 244-2, and bumps 246-3 may be formed over pillars 244-3. In some embodiments, the solder bumps (e.g., bump 246-1, bump 246-2, and bumps 246-3, respectively) may partially fill opening 232-1, opening 232-2, and openings 232-3, respectively. In some embodiments, bump 246-1, bump 246-2, bumps 246-3, or combinations thereof include a solder material (e.g., lead-based materials, such as Sn, Pb, Ni, Au, Ag, Cu, Bi, combinations thereof, mixtures of other electrically conductive materials, or the like). In some embodiments, the solder material includes a lead-free material. The bumps are formed by an electroplating process and/or other suitable process. In some embodiments, a reflow process (e.g., a thermal process) may be performed on the solder material. In some embodiments, bump 246-1, bump 246-2, bumps 246-3, or combinations thereof have a hemispherical shape, a spherical shape, an oval shape, or other suitable shape. In some embodiments, bump 246-1, bump 246-2, bumps 246-3, or combinations thereof are referred to as solder balls. In some embodiments, a diffusion barrier (including, for example, nickel) may be formed between the pillars and the bumps to prevent formation of intermetallic layers therebetween and/or to prevent the formation of voids.

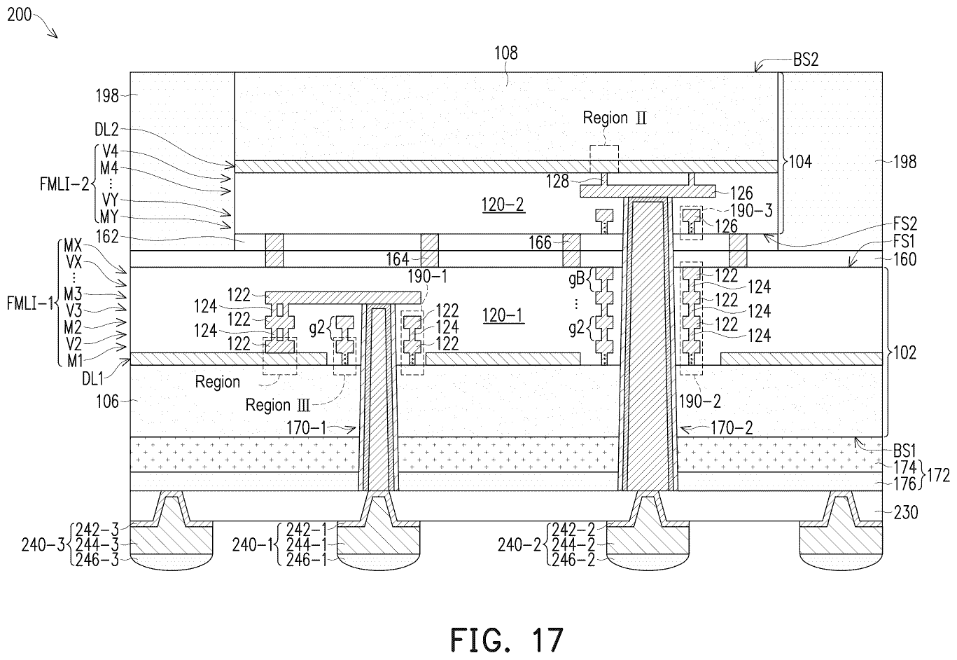

Referring to FIG. 17, carrier substrate 215 is removed by a suitable process, such as a grinding process, from the frontside of stacked chip structure 200, and stacked chip structure 200 is flipped back over, such that chip 102 and chip 104 provide a bottom die and a top die, respectively. Stacked chip structure 200 is configured as stacked chip structure 100A, and stacked chip structure 200 may be an IC package or portion thereof.

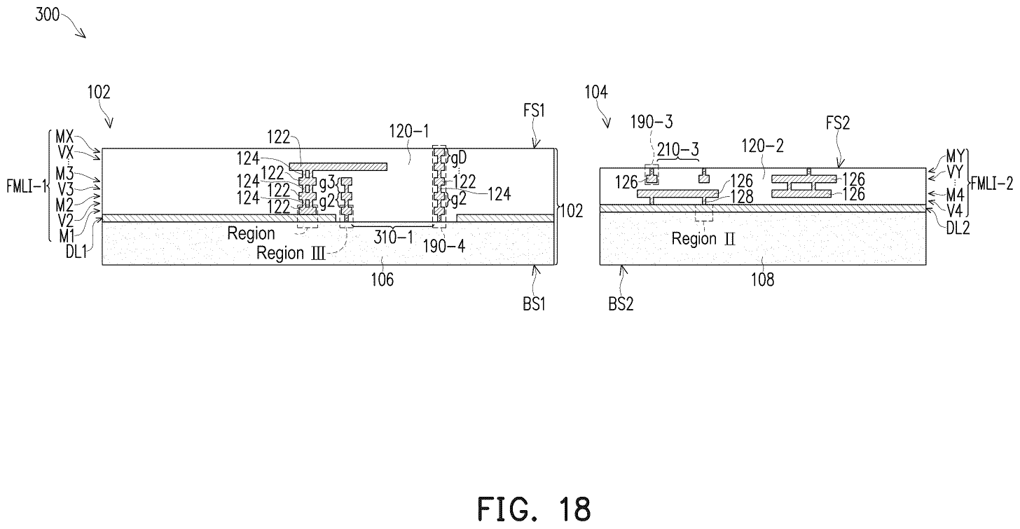

Referring to FIGS. 18-26, FIGS. 18-26 are cross-sectional views of a stacked chip structure 300, in portion or entirety, at various fabrication stages of forming a power delivery structure, such as the power delivery structure of stacked chip structure 100B of FIG. 2A, according to various aspects of the present disclosure. Fabrication of stacked chip structure 300 is similar to fabrication of stacked chip structure 200. Similar aspects therebetween are thus not repeated in the interest of simplicity and conciseness. FIGS. 18-26 have been simplified for the sake of clarity to better understand the inventive concepts of the present disclosure. Additional features can be added in stacked chip structure 300, and some of the features described below can be replaced, modified, or eliminated in other embodiments of stacked chip structure 300.

Referring to FIG. 18, stacked chip structure 300 undergoes processing similar to that described above with reference to FIG. 9. For example, after stacked chip structure 300 has undergoes FEOL processing (e.g., to form device layer DL1 and device layer DL2 of chip 102 and chip 104, respectively), stacked chip structure 300 may undergo MEOL processing and BEOL processing to form FMLI-1 structure over device layer DL1 and FMLI-2 structure over device layer DL2. Interconnect structure stacks of guard ring 190-4 (e.g., g0 level to g3 level of a side/wall proximate the power-delivery TSV for chip 102 (e.g., TSV 170-1) and g0 level to gD level of a side/wall proximate the power-delivery TSV for chip 104 (e.g., TSV 170-2)) may be formed over device layer DL1 while forming FMLI-1 structure. Interconnect structure stacks of guard ring 190-4 may be connected to device layer DL1, such as to doped regions formed in substrate 106. Guard ring 190-4 may be a metal ring (FIGS. 4A-4C) having an inner dimension that defines a dielectric region 310-1 of insulation layer 120-1. As described further herein, TSV 170-1 and TSV 170-2 will be formed in and extend through dielectric region 310-1. A portion of FMLI-1 structure (e.g., a respective metal line 122 of M4 level) overlaps guard ring 190-4 and will provide a TSV landing pad of chip 102. In some embodiments, guard ring 190-4 has a non-uniform height. For example, a side of guard ring 190-4 proximate the power-delivery TSV for chip 102 may extend from device layer DL1 to M3 level, and side of guard ring 190-4 proximate the power-delivery TSV for chip 104 may extend from device layer DL1 to MX level.

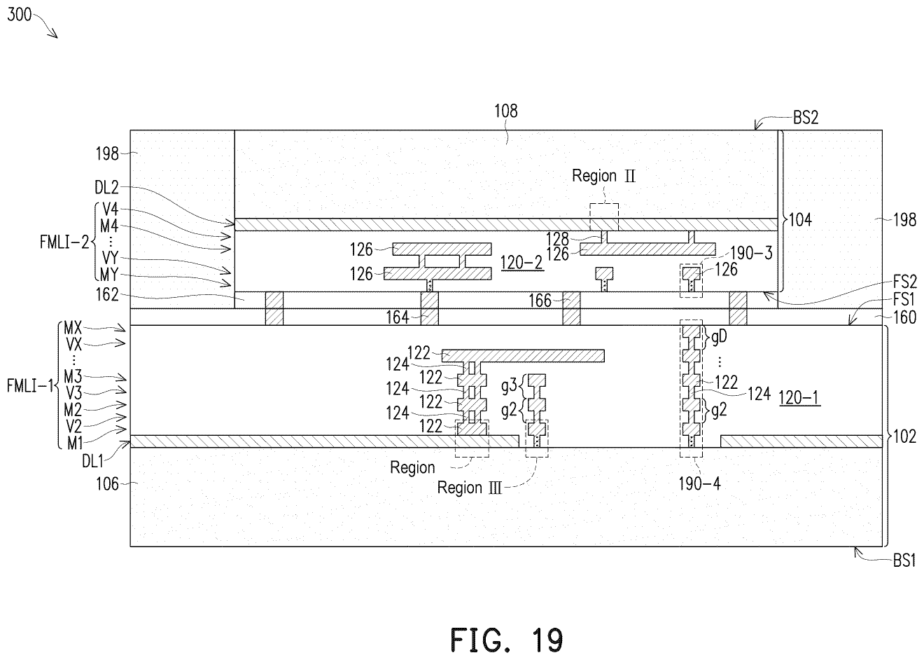

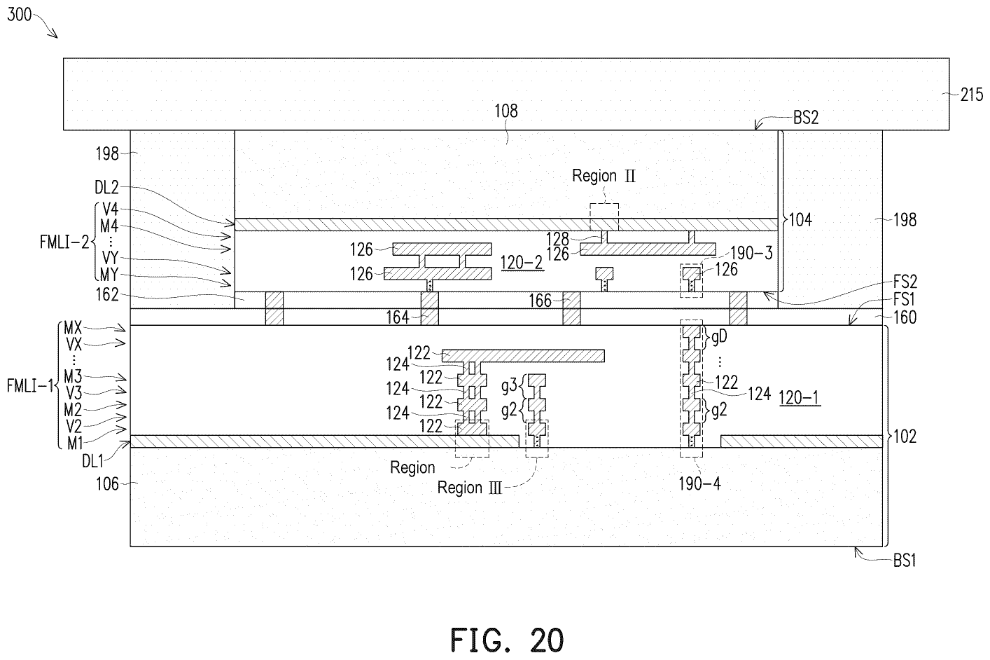

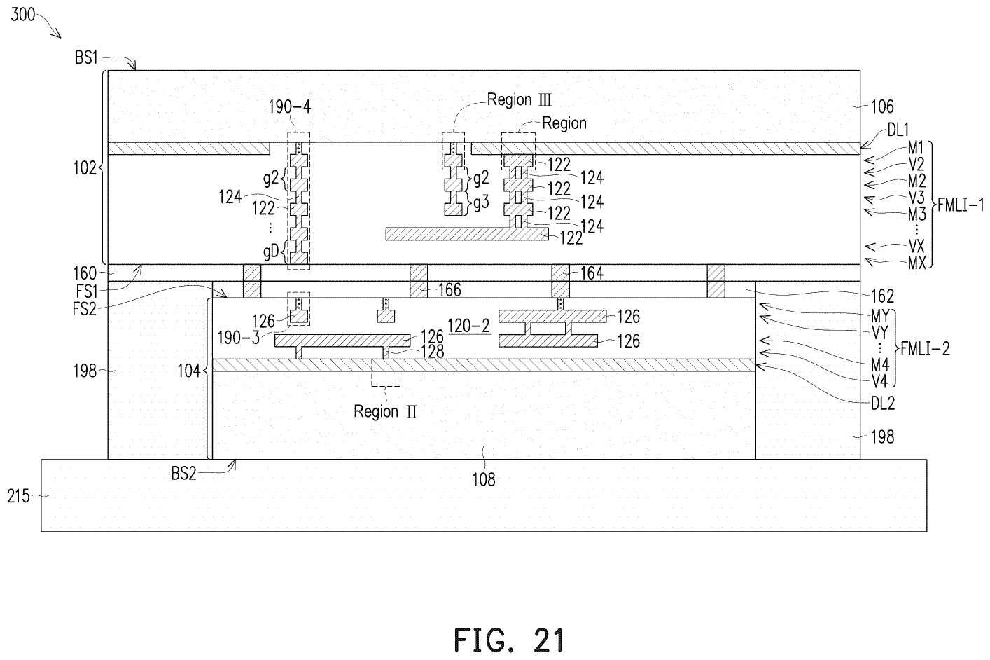

Referring to FIGS. 19-21, stacked chip structure 300 undergoes processing similar to that described above with reference to FIGS. 10-12, respectively. For example, chip 104 is face-to-face bonded to chip 102 to form stacked chip structure 300 (FIG. 19); encapsulant 198 and/or molding may be formed around chip 104 and over chip 102 (FIG. 19); carrier substrate 215 is attached to a frontside of stacked chip structure 300 (FIG. 20); and stacked chip structure 300 is flipped over and a thinning process is applied to backside BS1 of substrate 106 of chip 102 (FIG. 21). The bonding may include aligning a TSV landing pad of chip 104 (e.g., provided by a respective metal line 126 of M4 level in the depicted embodiment) with guard ring 190-4 of chip 102. For example, TSV landing pad of chip 104 may be aligned to overlap dielectric region 310-1 of chip 102. In some embodiments, the bonding includes aligning guard ring 190-3 with guard ring 190-4. For example, guard ring 190-3 may be edge aligned with guard ring 190-4.

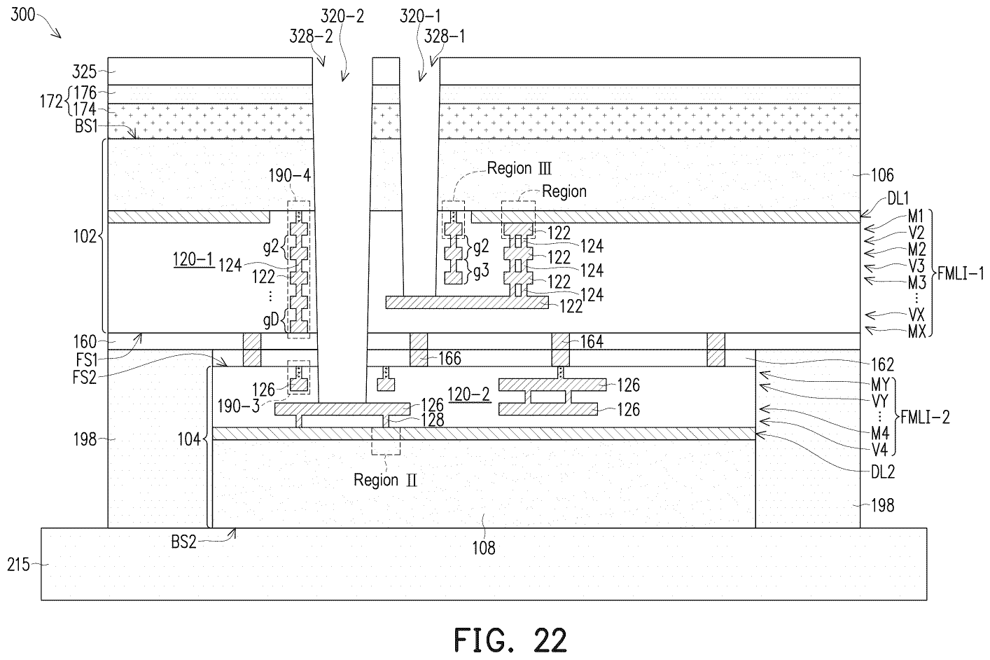

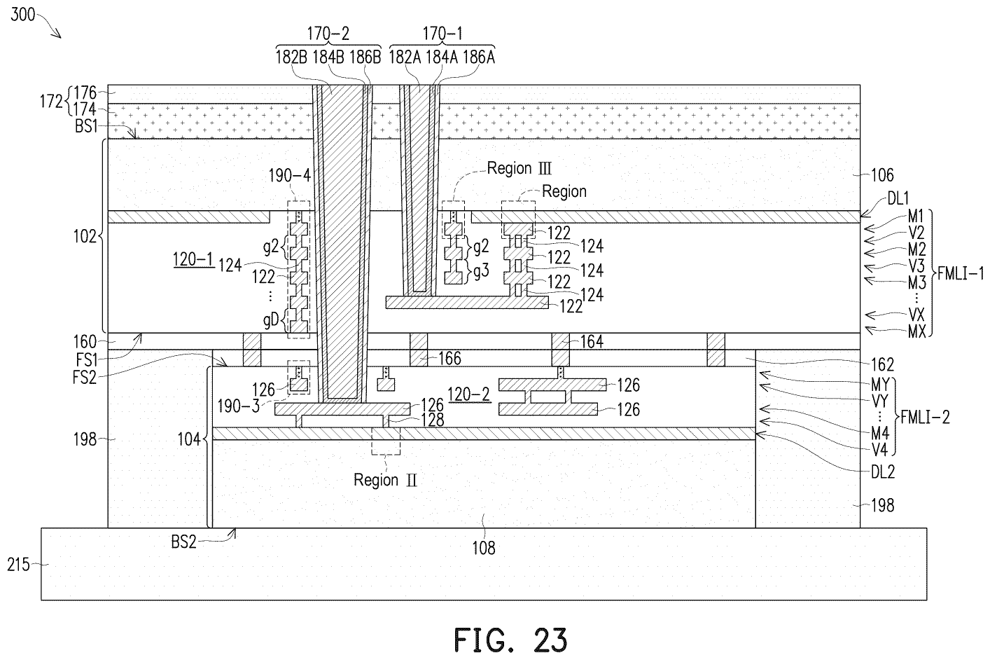

Referring to FIG. 22 and FIG. 23, stacked chip structure 300 undergoes processing similar to that described above with reference to FIG. 13 and FIG. 14, respectively. For example, TSV 170-1 and TSV 170-2 are formed simultaneously. Referring to FIG. 22, such processing may include forming a TSV trench 320-1 that exposes a TSV landing pad of chip 102 (e.g., provided by a respective metal line 122 of M4 level) and a TSV trench 320-2 that exposes a TSV landing pad of chip 104 (e.g., provided by a respective metal line 126 of M4 level). TSV trench 320-1 extends through substrate 106, device layer DL1, and into insulation layer 120-1. TSV trench 320-2 extends through substrate 106, device layer DL1, insulation layer 120-1, the chip bonding structure, and into insulation layer 120-2. TSV trench 320-1 and TSV trench 320-2 are both formed in dielectric region 310-1 of insulation layer 120-1, such that guard ring 190-4 is around both TSV trench 320-1 and TSV trench 320-2. In some embodiments, insulation layer 172 is formed over backside BS1 of chip 102 before forming the TSV trenches, TSV trench 320-1 and TSV trench 320-2 may extend through dielectric layer 174 and dielectric layer 176.

TSV trench 320-1 and TSV trench 320-2 may be formed similar to TSV trench 220-1 and TSV trench 220-2. In some embodiments, forming the TSV trenches includes forming a patterned mask layer 325 having openings (e.g., an opening 328-1 and an opening 328-2) therein that overlap dielectric regions defined by guard rings of chip 102 and/or chip 104. For example, opening 328-1 and opening 328-2 overlap dielectric region 310-1 of insulation layer 120-1, which is defined by guard ring 190-4 of chip 102, and opening 328-2 overlaps dielectric region 210-3, which is defined by guard ring 190-3. Patterned mask layer 325 may be similar to patterned mask layer 225 described above. In some embodiments, forming the TSV trenches includes etching chip 102 and chip 104 using patterned mask layer 325 as an etch mask. The etching may be similar that described above with reference to FIG. 13. The TSV etching process may remove patterned mask layer 325, in portion or entirety. In some embodiments, patterned mask layer 325 is removed by an etching process and/or a resist stripping process.

Referring to FIG. 23, forming the TSVs may further include filling the TSV trenches with an electrically conductive material. In some embodiments, filling TSV trench 320-1 and TSV trench 320-2 is performed in a manner similar to filling TSV trench 220-1 and TSV trench 220-2, such as described above with reference to FIG. 14. In such embodiments, TSV trench 320-1 and TSV trench 320-2 may be filled with a dielectric material that forms dielectric liners (e.g., dielectric liner 186A and dielectric liner 186B), a barrier material that forms barrier layers (e.g., barrier layer 184A and barrier layer 184B), and a bulk electrically conductive material that forms electrically conductive cores (e.g., electrically conductive core 182A and electrically conductive core 182B) of TSV 170-1 and TSV 170-2. In some embodiments, a planarization process performed when filling the TSV trenches may remove patterned mask layer 325.

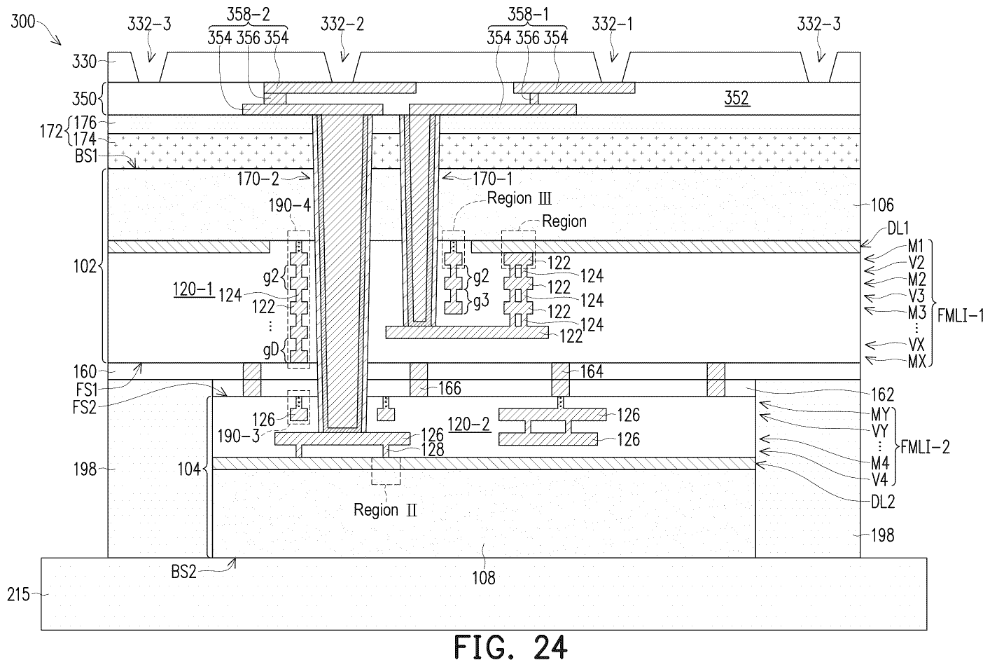

Referring to FIG. 24, stacked chip structure 300 undergoes processing similar to that described above with reference to FIG. 15. For example, a patterned passivation layer 330 having openings therein (e.g., an opening 332-1, an opening 332-2, and openings 332-3) may be formed over backside BS1 of chip 102. Patterned passivation layer 330 may be configured and formed similar to patterned passivation layer 230. In some embodiments, because TSVs are spaced more closely when arranged in a TSV cluster, a redistribution layer (RDL) structure 350 may be formed over backside BS1 of chip 102 before forming patterned passivation layer 330. RDL structure 350 may electrically connect TSV 170-1 and TSV 170-2 to respective connectors, which may be used for external connection (e.g., to respective power supply sources). In some embodiments, RDL structure 350 redistributes connectors to different locations, for example, to increase spacing between connectors for TSVs of a TSV cluster. In some embodiments, RDL structure 350 redistributes a layout of connections between devices and/or components of chip 102 and/or chip 104 to facilitate signal transmission and/or power transmission.

RDL structure 350 may include an insulation layer 352 having RDL lines 354 and RDL via(s) 356 disposed therein. RDL lines 354 and RDL vias 356 may be configured to provide an RDL interconnect (or route) 358-1 and an RDL interconnect (or route) 358-2. RDL interconnect 358-1 may electrically connect TSV 170-1 to a bump structure and/or external circuitry, and RDL interconnect 358-2 may electrically connect TSV 170-2 to a bump structure and/or external circuitry. RDL interconnect 358-1 and RDL interconnect 358-2 may each include a respective RDL via 356 disposed between a respective lower RDL line 354, which is disposed on TSV 170-1 or TSV 170-2, and a respective upper RDL line 354. In such embodiments, openings in patterned passivation layer 330 expose RDL structure 350, instead of TSVs. For example, opening 332-1 exposes upper RDL line 354 of RDL interconnect 358-1, opening 332-2 exposes upper RDL line 354 of RDL interconnect 358-2, and openings 332-3 expose insulation layer 352. RDL interconnect 358-1 and RDL interconnect 358-2 thus redistribute connection to TSV 170-1 and TSV 170-2 to different locations.

Insulation layer 352 includes an electrically insulating material, such as a polymer material (e.g., polyimide and/or BCB) and/or a dielectric material, and insulation layer 352 may have a multilayer structure (e.g., lower RDL lines 354 may be disposed in a first dielectric layer, RDL vias 356 may be disposed in a second dielectric layer, and upper RDL lines 354 may be disposed in a third dielectric layer). RDL lines 354 and RDL vias 356 include electrically conductive material, which may include aluminum, copper, titanium, tantalum, tungsten, ruthenium, cobalt, iridium, palladium, platinum, nickel, tin, gold, silver, other suitable metals, alloys thereof, silicides thereof, or combinations thereof. In some embodiments, RDL lines 354 and RDL vias 356 include the same electrically conductive materials. In some embodiments, RDL lines 354 and RDL vias 356 include different electrically conductive materials. In some embodiments, RDL lines 354 and/or RDL vias 356 have a multilayer structure.

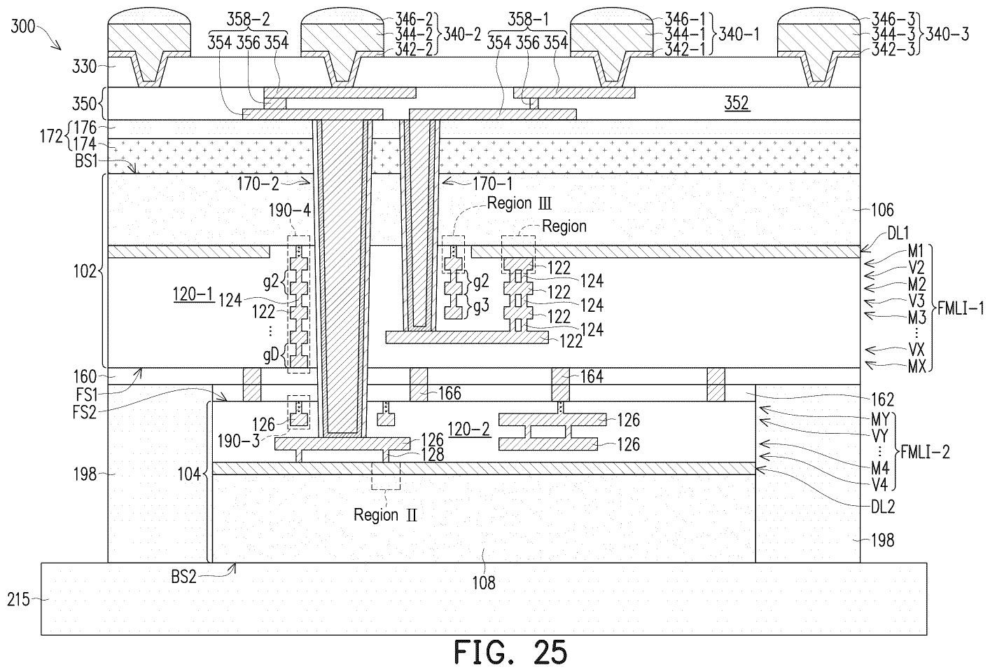

Referring to FIG. 25, stacked chip structure 300 undergoes processing similar to that described above with reference to FIG. 16. For example, a connector 340-1 is formed in opening 332-1 and over upper RDL line 354 of RDL interconnect 358-1 (which is connected to TSV 170-1), a connector 340-2 is formed in opening 332-2 and over upper RDL line 354 of RDL interconnect 358-2 (which is connected to TSV 170-2), and connectors 340-3 are formed in openings 332-3 and over insulation layer 350. Chip 102 and chip 104 may be electrically connected to external circuitry, another chip, a package substrate, a PCB, an interposer, other package component, or combinations thereof, by connector 340-1 and connector 340-2, respectively. For example, TSV 170-1 may be electrically connected to a power supply source by connector 340-1 (and RDL interconnect 358-1), where the power supply source may be configured to provide voltage v1 to chip 102, and TSV 170-2 may be electrically connected to a power supply source by connector 340-2 (and RDL interconnect 358-2), where the power supply source may be configured to provide voltage v2 to chip 104. Connector 340-1, connector 340-2, and connectors 340-3 may be formed by a bumping process, such as described above, and connector 340-1, connector 340-2, and connectors 340-3 may be similar to connector 240-1, connector 240-2, and connectors 240-3, respectively. For example, connector 340-1 may include a UBM layer 342-1, a pillar 344-1, and a bump 346-1; connector 340-2 may include a UBM layer 342-2, a pillar 344-2, and a bump 346-2; and connectors 340-3 may include a UBM layer 342-3, a pillar 344-3, and a bump 346-3. The UBM layers, the pillars, and the bumps of connector 340-1, connector 340-2, and connectors 340-3 may be configured and formed similar to the UBM layers, the pillars, and the bumps of connector 240-1, connector 240-2, and connectors 240-3, respectively.

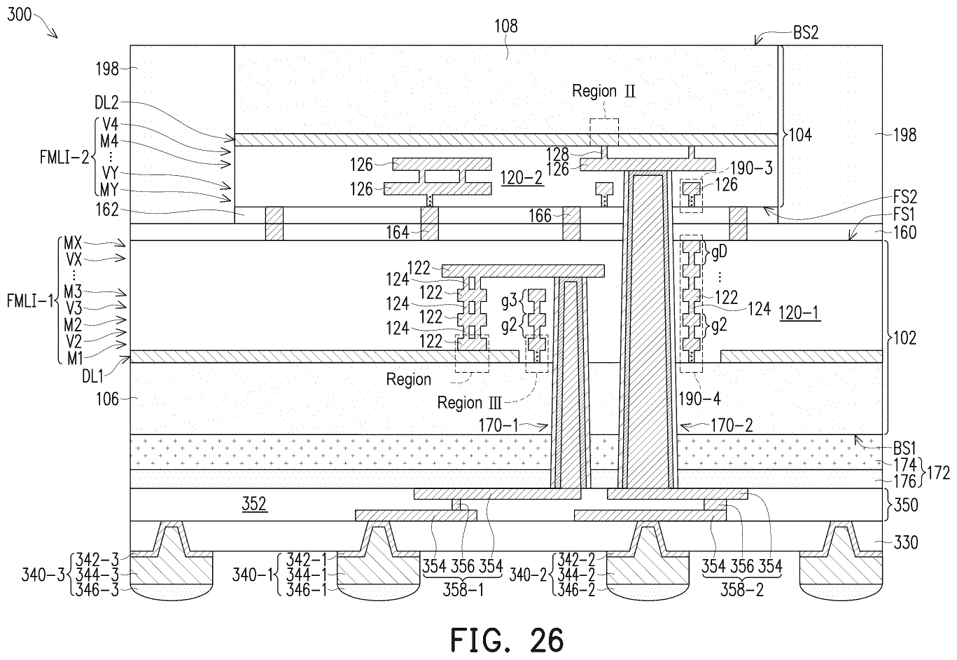

Referring to FIG. 26, stacked chip structure 300 undergoes processing similar to that described above with reference to FIG. 17. For example, carrier substrate 215 is removed by a suitable process from the frontside of stacked chip structure 300, and stacked chip structure 300 is flipped back over, such that chip 102 and chip 104 provide a bottom die and a top die, respectively, of stacked chip structure 300. Stacked chip structure 300 is configured as stacked chip structure 100B, and stacked chip structure 300 may be an IC package or portion thereof. In stacked chip structure 100B, since the power-delivery TSVs are directly connected to the chips, power-delivery TSVs may overlap chip bonds, and it is not necessary to adjust spacing between chip bonds of the chip bonding structure to accommodate for the TSV cluster. For example, in stacked chip structure 300, the short power-delivery TSV (e.g., TSV 170-1) may overlap a chip bond (e.g., formed by a respective bonding pad 164 and a respective bonding pad 166).

Through via power delivery structures for chip stacks and methods of fabrication thereof are disclosed herein. The present disclosure provides for many different embodiments. An exemplary stacked chip structure includes a first chip attached to a second chip. The first chip has a first substrate, a first device layer, and a first interconnect structure. The second chip has a second substrate, a second device layer, and a second interconnect structure. The stacked chip structure further includes a first through via and a second through via. The first through via extends through the first substrate, through the first device layer, through the first interconnect structure, and into the second interconnect structure. The second through via extends through the first substrate, through the first device layer, and into the first interconnect structure. In some embodiments, the stacked chip structure further includes a first guard ring around the first through via and a second guard ring around the second through via. In some embodiments, the stacked chip structure further includes a guard ring around the first through via and the second through via. In some embodiments, the first interconnect structure is bonded to the second interconnect structure.

In some embodiments, the first through via has a first critical dimension, the second through via has a second critical dimension, and the first critical dimension is different than the second critical dimension. In some embodiments, the first through via has a first aspect ratio, the second through via has a second aspect ratio, and the first aspect ratio is about equal to the second aspect ratio. In some embodiments, the first through via is electrically connected to the second device layer (e.g., via the second interconnect structure) and the second through via is electrically connected to the first device layer (e.g., via the first interconnect structure). In some embodiments, power is delivered to the second device layer by the first through via and to the first device layer by the second through via. In some embodiments, the first through via is connected to a first voltage and the second through via is connected to a second voltage.

An exemplary integrated circuit (IC) package includes a first die that is face-to-face bonded with a second die. The first die includes a first device layer and the second die includes a second device layer. The IC package further includes a first power-delivery through via that extends through the first die and into the second die. The first power-delivery through via is connected to the second device layer. The IC package further includes a second power-delivery through via that extends into the first die. The second power-delivery through via is connected to the first device layer. In some embodiments, the first die further includes a first routing structure, and the second die further includes a second routing structure. The second power-delivery through via may be connected to the first device layer via the first routing structure, and the first power-delivery through via may be connected to the second device layer via the second routing structure. In some embodiments, the IC package further includes a third die that is face-to-back bonded with the first die and a third power-delivery through via. The third die includes a third device layer. The first power-delivery through via further extends through the third die, and the second power-delivery through via further extends through the third die. The third power-delivery through via extends into the third die and is connected to the third device layer.

In some embodiments, the first die includes a first guard ring and a second guard ring. The first power-delivery through via extends through the first guard ring, and the second power-delivery through via extends through the second guard ring. The first guard ring has a first height, the second guard ring has a second height, and the first height is greater than the second height. In some embodiments, the first die includes a guard ring. The first power-delivery through via extends through the guard ring, and the second power-delivery through via extends through the guard ring. The guard ring has a first side proximate the first power-delivery through via and a second side proximate the second power-delivery via. The first side has a first height, the second side has a second height, and the first height is greater than the second height.

An exemplary method includes bonding a first chip to a second chip and forming a first through via and a second through via. The first chip has a first substrate, a first device layer, and a first interconnect structure. The second chip has a second substrate, a second device layer, and a second interconnect structure. The first through via extends through the first substrate, through the first device layer, through the first interconnect structure, and into the second interconnect structure. The second through via extends through the first substrate, through the first device layer, and into the first interconnect structure. In some embodiments, the method further includes forming the first through via and the second through via simultaneously. In some embodiments, the method further includes performing a thinning process to reduce a thickness of the first substrate after the bonding and before forming the first through via and the second through via.

In some embodiments, forming the first through via and the second through via includes performing an etching process that forms a first through via opening and a second through via opening and depositing electrically conductive material into the first through via opening and the second through via opening. The first through via opening extends through the first substrate, through the first device layer, through the first interconnect structure, and into the second interconnect structure. The first through via opening may exposes a first landing pad. The second through via opening extends through the first substrate, through the first device layer, and into the first interconnect structure. The second through via opening exposes a second landing pad.

In some embodiments, the method further includes forming a guard ring in the first interconnect structure, and the first through via and the second through via are formed through the guard ring. In some embodiments, the method further includes forming a first guard ring and a second guard ring in the first interconnect structure, the first through via is formed through the first guard ring, and the second through via is formed through the second guard ring.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A power-delivery structure for a die stack comprising:
a power-delivery through via cluster disposed in a first die of the die stack, wherein the power-delivery through via cluster includes:
a first power-delivery through via that extends entirely through the first die from a first side of the first die to a second side of the first die, wherein the first power-delivery through via is configured to deliver power to a second die of the die stack,
a second power-delivery through via that extends partially through the first die from the first side, wherein the second power-delivery through via is configured to deliver power to the first die of the die stack; and
a guard ring disposed in an insulation structure of the first die of the die stack, wherein the first power-delivery through via and the second power-delivery through via are disposed in a region of the insulation structure encompassed by the guard ring.

2. The power-delivery structure of claim 1, wherein the first power-delivery through via has a first diameter, the second power-delivery through via has a second diameter, and the first diameter is greater than the second diameter.

3. The power-delivery structure of claim 2, wherein the first diameter is less than about 15 μm, and the second diameter is less than about 15 μm.

4. The power-delivery structure of claim 2, wherein a first ratio of a first height of the first power-delivery through via to the first diameter of the first power-delivery through via is about the same as a second ratio of a second height of the second power-delivery through via to the second diameter of the second power-delivery through via.

5. The power-delivery structure of claim 1, wherein a spacing between the first power-delivery through via and the second power-delivery through via is at least 0.5 μm.

6. The power-delivery structure of claim 1, wherein:
the first power-delivery through via lands on a first through via landing pad, wherein the first through via landing pad is disposed in at least a fourth level of a first frontside multilayer interconnect structure of the first die; and
the second power-delivery through via lands on a second through via landing pad, wherein the second through via landing pad is disposed in at least a fourth level of a second frontside multilayer interconnect structure of the second die.

7. The power-delivery structure of claim 1, wherein the first power-delivery through via extends through an insulation portion of a bonding structure of the die stack that bonds the first die and the second die and into the second die of the die stack.

8. The power-delivery structure of claim 1, wherein the guard ring includes a first sidewall of a first height and a second sidewall of a second height, wherein the second height is different from the first height.

9. The power-delivery structure of claim 1, wherein the first side and the second side of the first die is a backside and a frontside, respectively, of the first die.

10. A power-delivery structure for a die stack comprising:
a guard ring disposed in an insulation structure of a die of the die stack; and
a power-delivery through via cluster disposed in a region of the insulation structure surrounded by the guard ring, wherein:
power-delivery vias of the power-delivery through via cluster have different heights, different diameters, and a same aspect ratio,
each power-delivery via of the power-delivery through via cluster delivers power to a respective die of the die stack,
at least one of the power-delivery vias of the power-delivery through via cluster extends partially through the die and delivers power to the die, and
other of the power-delivery vias of the power-delivery through via cluster extend entirely through the die of the die stack to their respective die.

11. The power-delivery structure of claim 10, wherein an aspect ratio of the power-delivery vias of the power-delivery through via cluster is about 5 to about 20.

12. The power-delivery structure of claim 10, wherein the guard ring includes sides extending different distances through the insulation structure of the die.

13. The power-delivery structure of claim 10, wherein:
the at least one of the power-delivery vias of the power-delivery through via cluster extends through a substrate of the die, through a device layer of the die, and into a multilayer interconnect structure of the die; and
the other of the power-delivery vias of the power-delivery through via cluster extend through the substrate of the die, through the device layer of the die, and through the multilayer interconnect structure of the die.

14. The power-delivery structure of claim 10, wherein the other of the power-delivery vias of the power-delivery through via cluster extend through an insulation portion of at least one die bonding structure of the die stack.

15. The power-delivery structure of claim 10, wherein each power-delivery via of the power-delivery through via cluster is connected to an external power source.

16. The power-delivery structure of claim 10, wherein the power-delivery through via cluster is a 1×2 power-delivery through via cluster, a 2×1 power-delivery through via cluster, a 2×2 power-delivery through via cluster, a 2×3 power-delivery through via cluster, or a 2××3 power-delivery through via cluster.

17. A method comprising:
forming a guard ring in an insulation structure of a first die; and
after stacking the first die over a second die, forming a power-delivery through via cluster in a region of the insulation structure encompassed by the guard ring, wherein the forming the power-delivery through via cluster includes:
simultaneously forming a first through via opening and a second through via opening in the region of the insulation structure, wherein:
the first through via opening extends entirely through the first die from a first side of the first die to a second side of the first die and the first through via opening extends into the second die, and
the second through via opening extends partially through the first die from the first side, and
forming a first power-delivery through via for delivering power to the second die in the first through via opening, and
forming a second power-delivery through via for delivering power to the first die in the second through via opening.

18. The method of claim 17, further comprising forming the first power-delivery through via in the first through via opening and forming the second power-delivery through via in the second through via opening simultaneously.

19. The method of claim 17, wherein the forming the first through via opening and the second through via opening in the region of the insulation structure includes providing the first through via opening and the second via opening with a same aspect ratio.

20. The method of claim 19, wherein the forming the first through via opening and the second through via opening in the region of the insulation structure includes providing the first through via opening and the second via opening with different diameters.
